(19) United States
(12) Patent Application Publication
(10) Pub. No.: US 2026/0282870 A1
(43) Pub. Date: Sep. 17, 2026

(54) SEMICONDUCTOR MEMORY DEVICE

(71) Applicant: Samsung Electronics Co., Ltd., Suwon-si (KR)

(72) Inventors: Cheonbae Kim, Suwon-si (KR); Woo Choel Noh, Suwon-si (KR)

(21) Appl. No.: 19/419,372

(22) Filed: Dec. 15, 2025

(30) Foreign Application Priority Data
Mar. 17, 2025 (KR) 10-2025-0033853

(51) Int. Cl. H10W 20/20; H10B 12/00; H10D 80/30; H10W 72/90

(52) U.S. Cl. CPC H10W 20/213; H10B 12/315; H10B 12/482; H10B 12/488; H10D 80/30; H10W 72/9226; H10W 72/923

(57) ABSTRACT

A semiconductor memory device includes a first semiconductor structure including a first semiconductor substrate and a first semiconductor element layer on a first surface of the first semiconductor substrate, and a second semiconductor structure on the first semiconductor structure, the second semiconductor structure including a second semiconductor substrate and a second semiconductor element layer on a second surface of the second semiconductor substrate. The second semiconductor structure includes a first via structure vertically penetrating the second semiconductor substrate and connected to the second semiconductor element layer, the first via structure is exposed on a third surface of the second semiconductor substrate, and a passivation layer covering the third surface. The second semiconductor substrate includes a recess region provided on the third surface and surrounding the first via structure. The passivation layer includes a protrusion fills the recess region. The passivation layer is in contact with the first via structure.

### CROSS-REFERENCE TO RELATED APPLICATION

This U.S. non-provisional patent application claims priority under 35 U.S.C. §119 to Korean Patent Application No. 10-2025-0033853, filed on March 17, 2025, in the Korean Intellectual Property Office, the entire contents of which are hereby incorporated by reference.

### BACKGROUND

A semiconductor memory device may include a number of circuit regions therein. For example, a semiconductor memory device may have a cell array region as a memory element and a peripheral region in which circuits for driving the cell array region and inputting and outputting data are formed. The electrical characteristics required for elements arranged in respective regions may vary from region to region.

On the other hand, there is a need to form more circuits in a limited area of a chip region while the semiconductor memory device is highly integrated. Therefore, there is a need to reduce a form factor of the semiconductor memory device and improve reliability by optimizing elements for each regions. In accordance with high integration of the semiconductor memory device, techniques have been proposed to improve the degree of integration in such a way that different circuits are formed on respective wafers and then bonded thereto.

### SUMMARY

Some aspects of the present disclosure provide semiconductor memory devices with improved electrical characteristics and structural stability.

Some aspects of the present disclosure provide methods for manufacturing a semiconductor memory device with a low occurrence of defects.

According to some implementations of the present disclosure, a semiconductor memory device may include: a first semiconductor structure including a first semiconductor substrate and a first semiconductor element layer provided on a first surface of the first semiconductor substrate; and a second semiconductor structure disposed on the first semiconductor structure and including a second semiconductor substrate and a second semiconductor element layer provided on a second surface of the second semiconductor substrate. The second semiconductor structure may include: a first via structure vertically penetrating the second semiconductor substrate and connected to the second semiconductor element layer, the first via structure being exposed on a third surface of the second semiconductor substrate opposite to the second surface; and a passivation layer covering the third surface of the second semiconductor substrate. The second semiconductor substrate may include a recess region provided on the third surface and surrounding the first via structure. The passivation layer may include a protrusion fills the recess region. The passivation layer may be in contact with the first via structure.

According to some implementations of the present disclosure, a semiconductor memory device may include: a first semiconductor substrate including a cell array region; a first interlayer insulating layer covering the first semiconductor substrate; first wirings provided in the first interlayer insulating layer and electrically connected to the cell array region; a first bonding layer disposed on the first interlayer insulating layer; a second semiconductor substrate disposed on the first bonding layer , the second semiconductor substrate including a logic region electrically connected to the cell array region; a transistor provided on a top surface of the second semiconductor substrate on the logic region; a second interlayer insulating layer covering the top surface of the second semiconductor substrate; second wirings provided in the second interlayer insulating layer and electrically connected to the transistor; a passivation layer covering a bottom surface of the second semiconductor substrate; a second bonding layer covering a bottom surface of the passivation layer and contacted with the first bonding layer; and a via structure provided in a via hole vertically penetrating the second semiconductor substrate. The second semiconductor substrate may include an inclined surface connecting an inner surface of the via hole and the bottom surface of the semiconductor substrate. The via structure may be horizontally spaced apart from the bottom surface of the second semiconductor substrate. The second bonding layer may include a via pattern. The via pattern penetrates the passivation layer to be connected to a bottom surface of the via structure, and is horizontally spaced apart from the bottom surface of the second semiconductor substrate.

According to some implementations of the present disclosure, a semiconductor memory device may include: a first semiconductor substrate; a first semiconductor structure including a first semiconductor element layer provided on the first semiconductor substrate; a first bonding layer disposed on the first semiconductor structure; a second semiconductor substrate disposed on the first bonding layer; a second semiconductor structure including a second semiconductor element layer provided on the second semiconductor substrate; a via structure vertically penetrating the second semiconductor substrate and exposed on a bottom surface of the second semiconductor substrate; a passivation layer covering the bottom surface of the second semiconductor substrate; and a second bonding layer covering the passivation layer and in contact with the first bonding layer. An upper portion of the via structure may be in contact with the second semiconductor substrate. A lower portion of the via structure may be horizontally spaced apart from the second semiconductor substrate. At least a portion of the passivation layer may extend between the lower portion of the via structure and the second semiconductor substrate. The first bonding layer may include a first insulating pattern and a first pad pattern in the first insulating pattern. The second bonding layer may include a second insulating pattern, a second pad pattern in the second insulating pattern, and a via pattern that penetrates the second insulating pattern and the passivation layer to be connected to a bottom surface of the via structure. The first pad pattern and the second pad pattern may be in contact with each other.

### BRIEF DESCRIPTION OF THE DRAWINGS

The above and other aspects, features, and advantages provided by the present disclosure will be more apparent from the following description taken in conjunction with the accompanying drawings, in which:

FIG. 1 is a block diagram of an example of a semiconductor memory device.

FIG. 2 is a perspective view illustrating an example of a semiconductor memory device.

FIG. 3 is a cross-sectional view illustrating an example of a semiconductor memory device.

FIGS. 4 to 9 are enlarged views of examples of region A of FIG. 3.

FIG. 10 is a cross-sectional view illustrating an example of a semiconductor memory device.

FIG. 11 is a cross-sectional view illustrating an example of a semiconductor memory device.

FIG. 12 is an enlarged view of region B of FIG. 11.

FIG. 13 is a cross-sectional view illustrating an example of a semiconductor memory device.

FIG. 14 is an enlarged view of region C of FIG. 13.

FIG. 15 is a cross-sectional view illustrating an example of a semiconductor memory device.

FIG. 16 is an enlarged view of region D of FIG. 15.

FIG. 17 is a cross-sectional view illustrating an example of a configuration of a plurality of semiconductor memory devices.

FIGS. 18 and 19 are cross-sectional views illustrating examples of semiconductor packages including semiconductor memory devices.

FIGS. 20A, 21A, 22A, 23A, 24A, 25A, and 26A are cross-sectional views illustrating an example of a method of manufacturing a semiconductor memory device, and FIGS. 20B, 21B, 22B, 23B, 24B, 25B, and 26B are enlarged views of regions of FIGS. 20A, 21A, 22A, 23A, 24A, 25A, and 26A, respectively.

### DETAILED DESCRIPTION

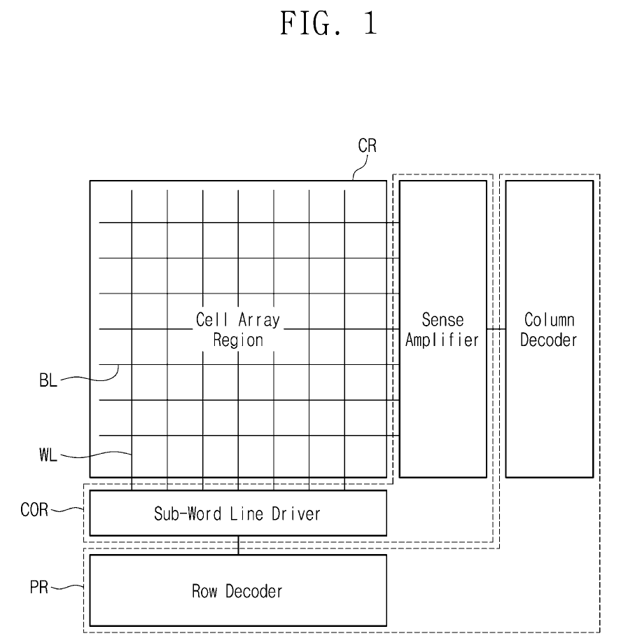

FIG. 1 is a block diagram of an example of a semiconductor memory device.

Referring to FIG. 1, a semiconductor memory device may be, for example, a DRAM. The semiconductor memory device may include a cell array region CR. Word lines WL and bit lines BL that intersect with each other may be disposed in the cell array region CR.

A core region COR may be adjacent to the cell array region CR. A sub-word line driver and a sense amplifier may be disposed in the core region COR. The sub-word line driver may select a particular word line in response to a row address signal or a refresh address signal. The amount of charge stored in a cell capacitor of a selected memory cell is very low, so it may not be directly converted to a digital signal and output to the outside. The sense amplifier may perform a function of amplifying a low amount of charge.

A peripheral circuit region PR may be adjacent to the core region COR. A row decoder and a column decoder may be disposed in the peripheral circuit region PR. The core region COR and the peripheral circuit region PR may be collectively referred to as a logic region. The row decoder may decode the row address signal or the refresh address signal. The column decoder may decode the column address signal and perform a selection operation on the bit lines BL.

The logic region including the core region COR and the peripheral circuit region PR may drive the cell array region CR.

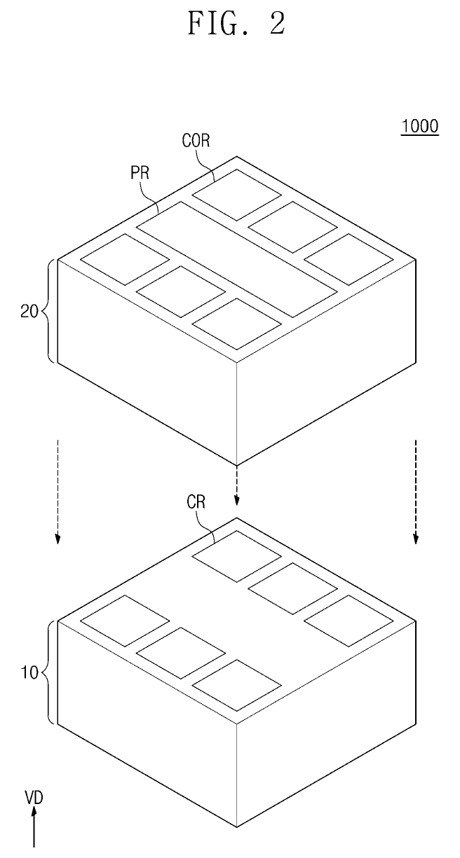

FIG. 2 is a perspective view illustrating an example of a semiconductor memory device.

Referring to FIG. 2, a memory chip 1000 may include a cell chip 10 and a core/peri chip 20 disposed in a vertical direction VD. The cell chip 10 and the core/peri chip 20 may vertically overlap each other. For example, as shown in FIG. 2, the core/peri chip 20 may be stacked on the cell chip 10.

In a plan view, the cell chip 10 may include a plurality of the cell array regions CR. The cell regions CR may be adjacent to each other in a horizontal direction. Each of the cell array regions CR may vertically overlap at least a portion of each of a plurality of the core regions COR described below. Each of the cell array regions CR may include a memory cell layer 110 described below. The memory cell layer 110 may store data.

In a plan view, the core/peri chip 20 may include the core regions COR and a peripheral circuit region PR. The core regions COR and the peripheral circuit region PR may be adjacent to each other in the horizontal direction. Each of the core regions COR may include a core bank. The core bank may include core circuits such as the sub-word line driver, the sense amplifier, the row decoder, the column decoder, a read/write circuit, and the like. The peripheral circuit region PR may include peripheral circuits such as a timing register, an address register, a data input register, a data output register, a data input/output terminal, and the like. The core regions COR and the peripheral circuit region PR may include a core/peri transistor 210 to be described later.

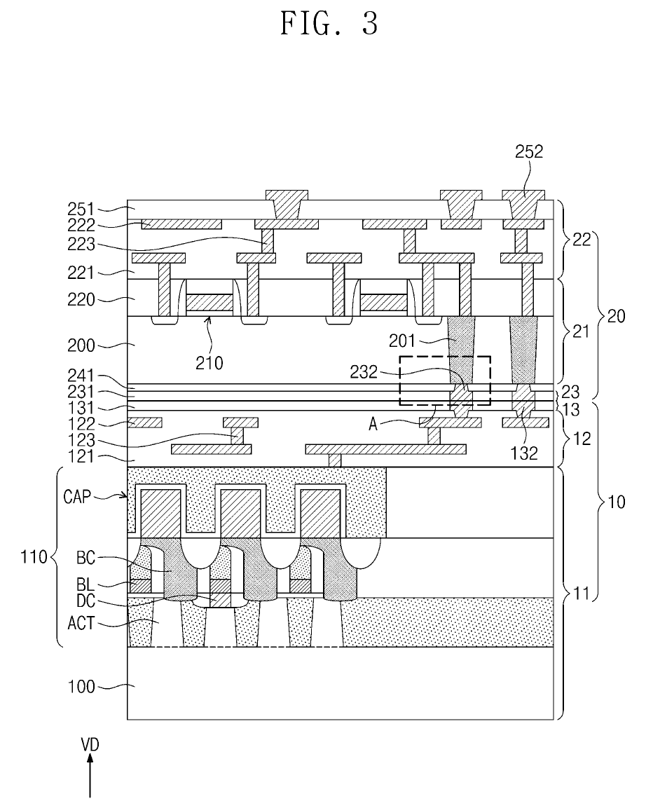

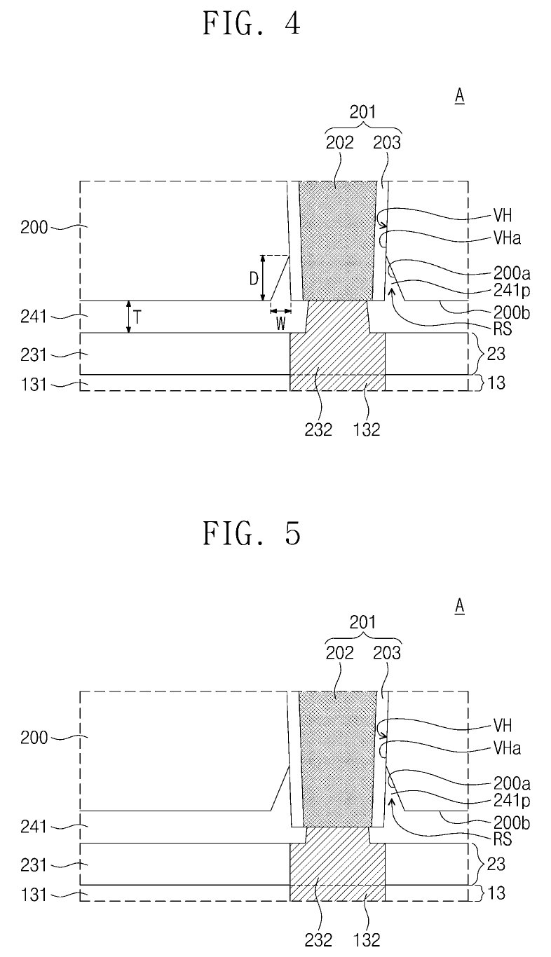

FIG. 3 is a cross-sectional view illustrating an example of a semiconductor memory device. FIGS. 4 to 9 are enlarged views of region A of FIG. 3.

Referring to FIG. 3, the cell chip 10 may include a data storage layer 11 and a cell wiring layer 12. The data storage layer 11 may include a cell semiconductor layer 100 and the memory cell layer 110. The cell semiconductor layer 100 may include a top surface and a bottom surface opposite to each other in the vertical direction VD. The top surface of the cell semiconductor layer 100 may be a front surface of the cell semiconductor layer 100. The memory cell layer 110 may be formed on the front surface of the cell semiconductor layer 100. The bottom surface of the cell semiconductor layer 100 may be a rear surface of the cell semiconductor layer 100. In this disclosure, the front surface is defined as a surface on which integrated elements or wirings in a semiconductor chip are formed, and the surface on which pads of the semiconductor chip are formed. The rear surface may be defined as an opposite surface to the front surface. The top surface of the cell semiconductor layer 100 may be an active surface of the cell semiconductor layer 100. The bottom surface of the cell semiconductor layer 100 may be an inactive surface of the cell semiconductor layer 100.

The cell semiconductor layer 100 may include a semiconductor material. For example, the cell semiconductor layer 100 may be a semiconductor substrate including a semiconductor material such as a single crystal silicon substrate, a silicon-germanium (Si-Ge) substrate, or a silicon on insulator (SOI) substrate. For example, the cell semiconductor layer 100 may be a semiconductor epitaxial layer including a semiconductor material.

The memory cell layer 110 may be a semiconductor element layer including at least one semiconductor element. The cell semiconductor layer 100 and the memory cell layer 110 may constitute one semiconductor structure. For example, the memory cell layer 110 may include at least one of various types of memory semiconductors. For example, the memory cell layer 110 may include a 2D memory such as a DRAM having a BCAT (Buried Channel Array Transistor) or VCT (Vertical Channel Transistor) structure. For example, the memory cell layer 110 may include a 3D memory such as VS DRAM (Vertically Stacked DRAM), 3D FeFET (Ferroelectric FET), and 3D monolithic. For example, as shown in FIG. 3, the memory cell layer 110 may include a DRAM cell structure including an active region ACT, a bit line node contact DC, the bit line BL, a storage node contact BC, a capacitor CAP, and the like. The word line may cross the active region ACT at a level lower than a top surface of the active region ACT. The memory cell layer 110 may be a portion of the cell array region CR described with reference to FIG. 2. The memory cell layer 110 may store data.

As another example, the memory cell layer 110 may include a DRAM for a VCT structure including a bit line, a channel pattern, a word line, a capacitor, and the like. The channel pattern may include at least one of a single crystal silicon, polysilicon, an oxide semiconductor material (e.g., InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc.), a two-dimensional material (e.g., graphene, etc.), or a transition metal dichalcogenide (TMD) including a transition metal element (e.g., Mo, W, V, Nb, Ta, Ti, etc.) and a chalcogen element (e.g., S, Se, Te, etc.).

The memory cell layer 110 and a cell wiring layer 12 may be sequentially provided on the top surface of the cell semiconductor layer 100.

The cell wiring layer 12 may be disposed on the data storage layer 11. The cell wiring layer 12 may include cell circuit wirings 122, cell contact plugs 123 electrically connecting the memory cell layer 110 and the cell circuit wirings 122, and a first interlayer insulating layer 121.

The memory cell layer 110 may be covered with the first interlayer insulating layer 121. The first interlayer insulating layer 121 may include a single-layer structure or multi-layer structure. The first interlayer insulating layer 121 may include at least one of silicon oxide (SiO or SiO₂), silicon nitride (SiN), silicon oxynitride (SiON), silicon carbonitride (SiCN), or a porous insulating layer.

Wirings electrically connected to the memory cell layer 110 may be disposed in the first interlayer insulating layer 121. The wirings may include cell wiring patterns 122 and 123 in the first interlayer insulating layer 121. For example, the cell wiring patterns 122, 123 may include the cell circuit wirings 122 for horizontal connection and the cell contact plugs 123 for vertical connection. The cell wiring patterns 122, 123 may vertically penetrate the first interlayer insulating layer 121 and be connected to the memory cell layer 110 (for example, the capacitor CAP) of the cell semiconductor layer 100. The cell wiring patterns 122, 123 may be provided between a top surface and a bottom surface of the first interlayer insulating layer 121. The cell wiring patterns 122, 123 may include, for example, copper (Cu) or tungsten (W).

The cell wiring patterns 122, 123 may have a damascene structure. For example, the cell wiring patterns 122, 123 may have a head portion and a tail portion integrally connected to each other. The cell circuit wirings 122 may be the head portion of the cell wiring patterns 122, 123, and the cell contact plugs 123 may be the tail portion of the cell wiring patterns 122, 123. The head portion and the tail portion of the cell wiring patterns 122, 123 may have a cross-section in the shape of ‘T’.

The head portion of the cell wiring patterns 122, 123 (e.g., the cell circuit wirings 122) may be a wiring portion or a pad portion that horizontally expands the wiring in the cell wiring layer 12. The cell circuit wirings 122 may not be exposed on the top surface of the first interlayer insulating layer 121.

The tail portion of the cell wiring patterns 122, 123, (e.g., the cell contact plugs 123) may be a via portion that vertically connects the wiring in the cell wiring layer 12. The tail portion may extend from a bottom surface of the head portion and may be connected to the capacitor CAP or a top surface of other cell circuit wirings 122 disposed thereunder.

A cell bonding layer 13 may be provided on the cell wiring layer 12. The cell bonding layer 13 may include a cell insulating pattern 131 and a cell pad pattern 132.

The cell pad pattern 132 may be provided on the top surface of the first interlayer insulating layer 121. The cell pad pattern 132 may vertically penetrate the first interlayer insulating layer 121 and be connected to the cell wiring patterns 122, 123. The cell wiring patterns 122, 123 may transmit a power signal or an input/output signal transmitted from the cell pad pattern 132 to the memory cell layer 110. The cell pad pattern 132 may include a metal material such as copper (Cu).

The cell insulating pattern 131 may cover the first interlayer insulating layer 121. The cell insulating pattern 131 may surround the cell pad pattern 132 on the top surface of the first interlayer insulating layer 121. A top surface of the cell insulating pattern 131 and a top surface of the cell pad pattern 132 may be substantially in the same level. The cell insulating pattern 131 may include silicon oxide (SiO or SiO₂), silicon nitride (SiN), silicon oxynitride (SiON), silicon carbonitride (SiCN), an insulating polymer, or a photosensitive polymer.

The core/peri chip 20 may be disposed on the cell chip 10. The core/peri chip 20 may include a driving layer 21, a core/peri wiring layer 22, and a core/peri bonding layer 23. The core/peri wiring layer 22 may be provided on the driving layer 21.

The driving layer 21 may include a core/peri semiconductor layer 200 and a core/peri transistor 210 on the core/peri semiconductor layer 200. The core/peri semiconductor layer 200 may include a top surface and a bottom surface opposite to each other in the vertical direction VD. The top surface of the core/peri semiconductor layer 200 may be a front surface of the core/peri semiconductor layer 200. The core/peri transistor 210 may be formed on the front surface of the core/peri semiconductor layer 200. The bottom surface of the core/peri semiconductor layer 200 may be a rear surface of the core/peri semiconductor layer 200. For example, the top surface of the core/peri semiconductor layer 200 may be an active surface of the core/peri semiconductor layer 200. The bottom surface of the core/peri semiconductor layer 200 may be an inactive surface of the core/peri semiconductor layer 200.

The core/peri semiconductor layer 200 may include a semiconductor material. For example, the core/peri semiconductor layer 200 may be a semiconductor substrate including a semiconductor material such as a single crystal silicon substrate, a silicon-germanium (Si-Ge) substrate, or a silicon on insulator (SOI) substrate. For example, the core/peri semiconductor layer 200 may be a semiconductor epitaxial layer including a semiconductor material.

The core/peri transistor 210 may be a transistor provided in a core circuit and a peripheral circuit. For example, as shown in FIG. 3, the core/peri transistor 210 may include a source and a drain formed on an upper portion of the core/peri semiconductor layer 200, a gate disposed on the front surface of the core/peri semiconductor layer 200 between the source and the drain, and a gate insulating layer interposed between the core/peri semiconductor layer 200 and the gate. In FIG. 3, the core/peri transistor 210 is illustrated as a planar transistor, but is not limited thereto, and various types of transistors may be used. The core/peri transistor 210 may be provided in plural. The plurality of core/peri transistors 210 may form an integrated circuit. The core/peri transistors 210 may constitute the core regions COR or the peripheral circuit region PR described with reference to FIG. 2.

The driving layer 21 may further include a second interlayer insulating layer 220. The second interlayer insulating layer 220 may cover the core/peri transistor 210 on the core/peri semiconductor layer 200. Although FIG. 3 illustrates that a top surface of the second interlayer insulating layer 220 exposes a top surface of the core/peri transistor 210, the layer configuration is not limited thereto. The second interlayer insulating layer 220 may include a single-layer structure or multiple-layer structure of at least one of silicon oxide (SiO or SiO₂), silicon nitride (SiN), silicon oxynitride (SiON), silicon carbonitride (SiCN), or a porous insulating layer.

The plurality of core/peri transistors 210 and the second interlayer insulating layer 220 may constitute a semiconductor element layer including at least one semiconductor element. The core/peri semiconductor layer 200, the core/peri transistors 210, and the second interlayer insulating layer 220 may constitute one semiconductor structure.

The driving layer 21 and the core/peri wiring layer 22 may be sequentially provided on the top surface of the core/peri semiconductor layer 200.

The core/peri wiring layer 22 may be disposed on the driving layer 21. The core/peri wiring layer 22 may include core/peri circuit wirings 222, core/peri contact plugs 223 electrically connecting the core/peri transistor 210 and the core/peri circuit wirings 222, and a third interlayer insulating layer 221.

The driving layer 21 may be covered with the third interlayer insulating layer 221. The third interlayer insulating layer 221 may include a single-layer structure or multi-layer structure of at least one of silicon oxide (SiO or SiO₂), silicon nitride (SiN), silicon oxynitride (SiON), silicon carbonitride (SiCN), or a porous insulating layer.

Wirings electrically connected to the core/peri transistor 210 may be disposed in the third interlayer insulating layer 221. The wirings may include core/peri wiring patterns 222, 223 embedded in the third interlayer insulating layer 221. For example, the core/peri wiring patterns 222, 223 may include core/peri circuit wirings 222 for horizontal connection and core/peri contact plugs 223 for vertical connection. The core/peri wiring patterns 222, 223 may vertically penetrate the third interlayer insulating layer 221 to be connected to the driving layer 21, for example, one of the source, drain, and gate electrode of the core/peri transistor 210. The core/peri wiring patterns 222, 223 may be positioned between a top surface and a bottom surface of the third interlayer insulating layer 221. The core/peri wiring patterns 222, 223 may include, for example, copper (Cu) or tungsten (W).

The core/peri wiring patterns 222, 223 may have a damascene structure. For example, the core/peri wiring patterns 222, 223 may have a head portion and a tail portion integrally connected to each other. The core/peri circuit wirings 222 may be a head portion of the core/peri wiring patterns 222, 223, and the core/peri contact plugs 223 may be a tail portion of the core/peri wiring patterns 222, 223. The head portion and the tail portion of the core/peri wiring patterns 222, 223 may have a cross-section in the shape of ‘T’.

The head portion of the core/peri wiring patterns 222, 223 (e.g., the core/peri circuit wirings 222) may be a wiring portion or a pad portion that horizontally expands the wiring in the core/peri wiring layer 22. At least a portion of the core/peri circuit wirings 222 may be exposed on the top surface of the third interlayer insulating layer 221. As another example, the core/peri circuit wirings 222 may be embedded in the third interlayer insulating layer 221 without being exposed on the top surface of the third interlayer insulating layer 221.

The tail portion of the core/peri wiring patterns 222, 223 (e.g., the core/peri contact plugs 223) may be a via portion that vertically connects the wiring in the core/peri wiring layer 22. The tail portion may extend from a bottom surface of the head portion and may be connected to a top surface of other core/peri circuit wirings 222 disposed below it. As another example, the tail portion may extend from the bottom surface of the head portion, and may penetrate the third interlayer insulating layer 221 and the second interlayer insulating layer 220 to be connected to the core/peri transistor 210.

A first passivation layer 251 may be provided on the third interlayer insulating layer 221 of the core/peri wiring layer 22. The first passivation layer 251 may cover the third interlayer insulating layer 221 and the core/peri wiring patterns 222, 223. The first passivation layer 251 may include silicon oxide (SiO or SiO₂), silicon nitride (SiN), silicon oxynitride (SiON), silicon carbonitride (SiCN), an insulating polymer, or a photosensitive polymer.

Chip pads 252 may be provided on a top surface of the first passivation layer 251. The chip pads 252 may vertically penetrate the first passivation layer 251 and be connected to the core/peri wiring patterns 222, 223. The core/peri wiring patterns 222, 223 may transfer an operating signal transferred from the chip pads 252 to the core/peri transistor 210. The chip pads 252 may include a metal material such as copper (Cu).

Referring to FIGS. 3 and 4, a via structure 201 may be provided in the core/peri chip 20. The via structure 201 may vertically penetrate the core/peri semiconductor layer 200 at one side of the core/peri transistor 210. For example, the core/peri semiconductor layer 200 may have a via hole VH that vertically penetrates the core/peri semiconductor layer 200. The via hole VH may extend from a bottom surface 200b to the top surface of the core/peri semiconductor layer 200. The via structure 201 may fill the via hole VH.

The via structure 201 may include a through via 202 extending in the vertical direction VD in the via hole VH and a via insulating layer 203 surrounding an outer surface of the through via 202.

The through via 202 may have a columnar shape extending in the vertical direction VD. For example, the through via 202 may vertically penetrate the core/peri semiconductor layer 200. A width of the through via 202 may decrease from the top surface to the bottom surface 200b of the core/peri semiconductor layer 200. A top surface of the through via 202 may be exposed on the top surface of the core/peri semiconductor layer 200. The core/peri wiring patterns 222, 223 of the core/peri wiring layer 22 may penetrate the third interlayer insulating layer 221 and the second interlayer insulating layer 220 to be connected to the top surface of the through via 202. The through via 202 may be electrically connected to the semiconductor element layer of the core/peri chip 20, i.e., the core/peri transistors 210, through the core/peri wiring patterns 222, 223. The through via 202 may be exposed on the bottom surface 200b of the core/peri semiconductor layer 200. The through via 202 may include a metal material such as copper (Cu) or tungsten (W).

The via insulating layer 203 may cover the outer surface of the through via 202. A thickness of the via insulating layer 203 may be substantially uniform. Here, the thickness of the via insulating layer 203 may be defined as a distance from the outer surface of the through via 202 to an outer surface of the via insulating layer 203, in a direction perpendicular to the outer surface of the through via 202. The via insulating layer 203 may include an insulating material. For example, the via insulating layer 203 may include silicon oxide (SiO or SiO₂), silicon nitride (SiN), or silicon oxynitride (SiON).

The via structure 201 may have a columnar shape extending in the vertical direction VD. For example, the via structure 201 may vertically penetrate the core/peri semiconductor layer 200. A width of the via structure 201 may decrease from the top surface to the bottom surface 200b of the core/peri semiconductor layer 200. A bottom surface of the via structure 201 may be located at the same vertical level as the bottom surface 200b of the core/peri semiconductor layer 200. As another example, as shown in FIG. 5, the bottom surface of the via structure 201 may be located at a lower vertical level than the bottom surface 200b of the core/peri semiconductor layer 200. For example, the via structure 201 may protrude downward from the bottom surface 200b of the core/peri semiconductor layer 200.

Referring again to FIGS. 3 and 4, the via structure 201 may fill the inside of the via hole VH. The via structure 201 may be in contact with an inner surface of an upper portion of the via hole VH. For example, an upper portion of the outer surface of the via structure 201 may be in contact with the core/peri semiconductor layer 200. A lower portion of the via structure 201 may be spaced apart from the inner surface of the via hole VH. For example, a lower portion of the outer surface of the via structure 201 may be spaced apart from the core/peri semiconductor layer 200. For example, the via hole VH may have an hourglass shaped cross-section. A width of the via hole VH may decrease as a distance from the top surface of the core/peri semiconductor layer 200, and may increase again from a specific point. The width of the via hole VH may decrease as a distance from the bottom surface 200b of the core/peri semiconductor layer 200, and may increase again from a specific point. Here, a portion of the inner surface of the via hole VH in contact with the via structure 201 is defined as a first inner surface VHa, and a portion of the inner surface of the via hole VH spaced apart from the via structure 201 is defined as a second inner surface 200a.

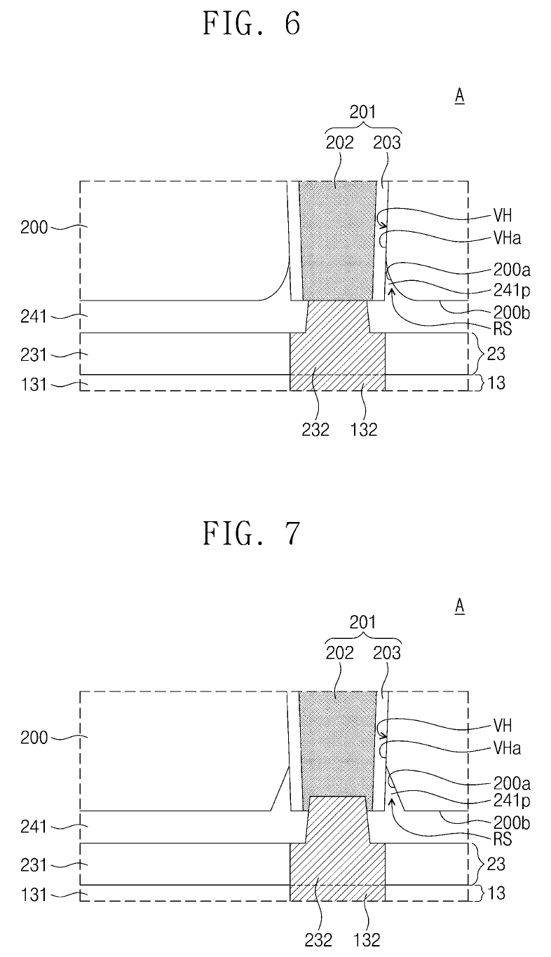

The core/peri semiconductor layer 200 may have a recess region RS provided in the bottom surface 200b of the core/peri semiconductor layer 200. The recess region RS may have a shape recessed from the bottom surface 200b of the core/peri semiconductor layer 200 toward the inside of the core/peri semiconductor layer 200. The recess region RS may surround the via structure 201 in a plan view. The recess region RS may be in contact with the via structure 201. The bottom surface 200b of the core/peri semiconductor layer 200 may be horizontally spaced apart from the via structure 201 with the recess region RS therebetween. The core/peri semiconductor layer 200 may have an inclined surface (e.g., second inner surface) 200a connecting the bottom surface 200b of the core/peri semiconductor layer 200 and the first inner surface VHa of the via hole VH. The inclined surface 200a may correspond to the second inner surface of the via hole VH. The recess region RS may be defined by the inclined surface 200a of the core/peri semiconductor layer 200 and the lower portion of the outer surface of the via structure 201. The inclined surface 200a of the core/peri semiconductor layer 200 may be a flat surface, as shown in FIG. 4. As another example, the inclined surface 200a of the core/peri semiconductor layer 200 may be a convex surface convex toward the via structure 201, as shown in FIG. 6.

A second passivation layer 241 may be provided on the bottom surface 200b of the core/peri semiconductor layer 200. The second passivation layer 241 may cover the bottom surface 200b of the core/peri semiconductor layer 200 and the via structure 201. The second passivation layer 241 may have a protrusion 241p filling the recess region RS. The protrusion 241pof the second passivation layer 241 may be in contact with the inclined surface 200a of the core/peri semiconductor layer 200 and the lower portion of the outer surface of the via structure 201. The second passivation layer 241 may include an insulating material. The second passivation layer 241 may include an oxide of a material of the core/peri semiconductor layer 200. For example, the second passivation layer 241 may include silicon oxide (SiO or SiO₂).

A depth D of the recess region RS may range from 40% to 60% of a thickness T of the second passivation layer 241. Here, the depth D of the recess region RS may correspond to a vertical distance from the bottom surface 200b of the core/peri semiconductor layer 200 to an uppermost end of the inclined surface 200a of the core/peri semiconductor layer 200. Here, the thickness T of the second passivation layer 241 may correspond to a vertical distance from the bottom surface 200b of the core/peri semiconductor layer 200 to a bottom surface of the second passivation layer 241. The depth D of the recess region RS may range from 400 Angstrom to 600 Angstrom.

A width W of the recess region RS may range from 40% to 60% of the thickness T of the second passivation layer 241. Here, the width W of the recess region RS may correspond to a horizontal distance between the bottom surface 200b of the core/peri semiconductor layer 200 and the bottom surface of the via structure 201. The width W of the recess region RS may range from 400 Angstrom to 600 Angstrom.

The core/peri bonding layer 23 may be provided on the bottom surface of the second passivation layer 241. The core/peri bonding layer 23 may include a core/peri insulating pattern 231 and a core/peri pad pattern 232.

A core/peri pad pattern 232 may be provided on the bottom surface of the second passivation layer 241. The core/peri pad pattern 232 may vertically penetrate the second passivation layer 241 and be connected to the bottom surface of the via structure 201. For example, a portion of the core/peri pad pattern 232 may be located on the bottom surface of the second passivation layer 241, and another portion of the core/peri pad pattern 232 may vertically extend from a top surface of the portion. For convenience of description, a portion of the core/peri pad pattern 232 located on the bottom surface of the second passivation layer 241 is referred to as a core/peri pad pattern 232, and other portion of the core/peri pad pattern 232 penetrating through the second passivation layer 241 is referred to as a via pattern. The via pattern may extend from a top surface of the core/peri pad pattern 232. The via pattern may penetrate the second passivation layer 241 to be connected to the bottom surface of the via structure 201. The via pattern may be horizontally spaced apart from the bottom surface 200b of the core/peri semiconductor layer 200. The core/peri pad pattern 232 may transmit and receive a power signal or an input/output signal transmitted from the driving layer 21 of the core/peri chip 20 to and from the cell chip 10. The core/peri pad pattern 232 may include a metal material such as copper (Cu).

According to some implementations of the present disclosure, the bottom of the core/peri semiconductor layer 200 may be horizontally spaced apart from the via structure 201 with a recess region RS therebetween. The bottom surface 200b of the core/peri semiconductor layer 200 may be horizontally spaced apart from the bottom surface of the via structure 201. Therefore, even if a width of the via pattern of the core/peri pad pattern 232 connected to the bottom surface of the via structure 201 is large or the via structure 201 and the via pattern are misaligned, the via pattern may not be in contact with the core/peri semiconductor layer 200. A leakage current due to contact between the core/peri pad pattern 232 and the core/peri semiconductor layer 200 may not occur, and a semiconductor memory device with improved electrical characteristics may be provided. In addition, since the core/peri pad pattern 232 made of metal is not in contact with the core/peri semiconductor layer 200 having high hardness, the core/peri semiconductor layer 200 may not be damaged by the core/peri pad pattern 232. That is, a semiconductor memory device with improved structural stability may be provided. This will be described in more detail below in conjunction with the disclosed example of a method for manufacturing a semiconductor memory device having the aforementioned spaced-apart characteristics.

The core/peri insulating pattern 231 may cover the bottom surface of the second passivation layer 241. The core/peri insulating pattern 231 may surround the core/peri pad pattern 232 on the bottom surface of the second passivation layer 241. The bottom surface of the core/peri insulating pattern 231 and the bottom surface of a core/peri pad pattern 232 may be substantially in the same level. The core/peri insulating pattern 231 may include silicon oxide (SiO or SiO₂), silicon nitride (SiN), silicon oxynitride (SiON), silicon carbonitride (SiCN), an insulating polymer, or a photosensitive polymer.

The core/peri chip 20 may be disposed on the cell chip 10. The core/peri chip 20 may be in direct contact with the cell chip 10.

On an interface between the cell chip 10 and the core/peri chip 20, the cell pad pattern 132 of the cell chip 10 may be bonded to the core/peri pad pattern 232 of the core/peri chip 20. The cell pad pattern 132 and the core/peri pad pattern 232 may be hybrid bonded to each other. In this description, the term “hybrid bonding” may denote a bonding in which two components of the same kind are merged at an interface. For example, the cell pad pattern 132 and the core/peri pad pattern 232 bonded to each other may have a continuous configuration, and an interface between the cell pad pattern 132 and the core/peri pad pattern 232 may be invisible. For example, the cell pad pattern 132 and the core/peri pad pattern 232 may be formed of the same material, and may thus have no interface between the cell pad pattern 132 and the core/peri pad pattern 232. The cell pad pattern 132 and the core/peri pad pattern 232 may be provided as a single component. For example, the cell pad pattern 132 and the core/peri pad pattern 232 may be bonded to form a single unitary piece. However, the configuration of the cell pad pattern 132 and the core/peri pad pattern 232 is not limited thereto. The cell pad pattern 132 and the core/peri pad pattern 232 may be formed of different materials. The cell pad pattern 132 and the core/peri pad pattern 232 may not have a continuous configuration, and an interface between the cell pad pattern 132, and the core/peri pad pattern 232 may be visible. The cell pad pattern 132 and the core/peri pad pattern 232 are not bonded to each other, and each of the cell pad pattern 132 and the core/peri pad pattern 232 may be provided as a separate component.

On the interface between the cell chip 10 and the core/peri chip 20, the cell insulating pattern 131 of the cell chip 10 may be in contact with the core/peri insulating pattern 231 of the core/peri chip 20. The cell insulating pattern 131 and the core/peri insulating pattern 231 may be made of the same material or different materials. The cell insulating pattern 131 and the core/peri insulating pattern 231 may not have a continuous configuration, and an interface between the cell insulating pattern 131 and the core/peri insulating pattern 231 may be visible. However, the configuration of the cell insulating pattern 131 and the core/peri insulating pattern 231 is not limited thereto. The cell insulating pattern 131 and the core/peri insulating pattern 231 may include oxide, nitride, or oxynitride hybrid bonding. For example, the cell insulating pattern 131 and the core/peri insulating pattern 231 bonded to each other may have a continuous configuration, and the interface between the cell insulating pattern 131 and the core/peri insulating pattern 231 may be invisible. For example, the cell insulating pattern 131 and the core/peri insulating pattern 231 may be bonded to form a single unitary piece.

In discussion of further examples below, a detailed description of technical features discussed with reference to FIGS. 3 to 6 will be omitted for convenience of description, and differences therebetween will be discussed in detail. The same reference numerals may be used for the same components as those of the semiconductor devices discussed above, and the description provided with respect to FIGS. 1 to 6 should be understood to apply to the following semiconductor devices, except where noted otherwise or suggested otherwise by context.

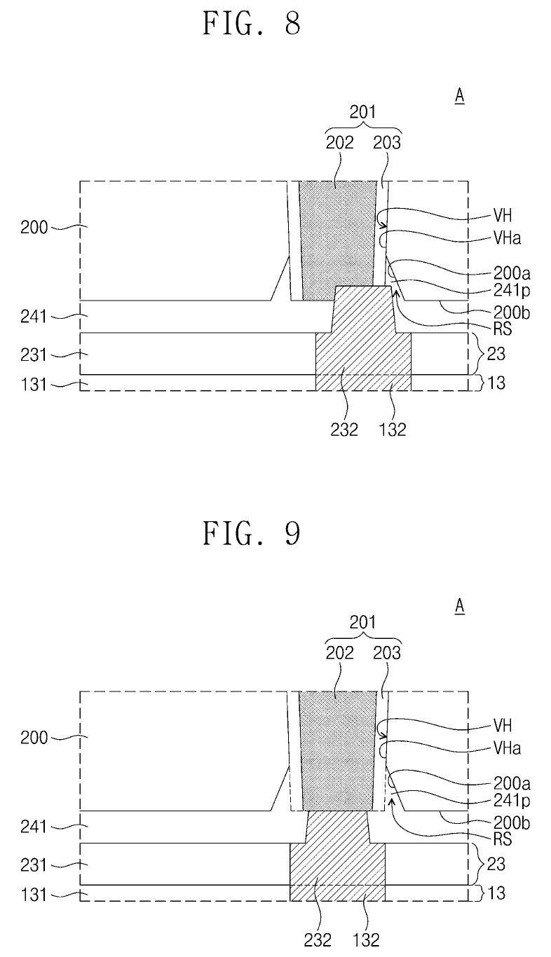

FIGS. 7 and 8 are enlarged views of examples of the area A of FIG. 3.

Referring to FIGS. 3 and 7, the via pattern of the core/peri pad pattern 232 may be inserted into the via structure 201. For example, the via pattern of the core/peri pad pattern 232 may extend from the bottom surface of the via structure 201 toward an inside of the via structure 201, e.g., may penetrate into the via structure 201 (e.g., may penetrate into the through via 202). A top surface of the via pattern of the core/peri pad pattern 232 may be located at a higher vertical level than the bottom surface of the via structure 201. The top surface (or topmost end) of the via pattern of the core/peri pad pattern 232 may be located at a higher level than the bottom surface 200b of the core/peri semiconductor layer 200.

Although FIG. 7 shows that the via pattern of the core/peri pad pattern 232 and the via structure 201 are vertically aligned, their relative arrangement is not limited thereto. For example, referring to FIG. 8, the via pattern of the core/peri pad pattern 232 and the via structure 201 may be vertically misaligned. For example, the via pattern of the core/peri pad pattern 232 may be shifted horizontally from the outer surface of the via structure 201. The via pattern of the core/peri pad pattern 232 may be more adjacent to the bottom surface 200b of the core/peri semiconductor layer 200, e.g., may be closer to one lateral side of the bottom surface 200b or closer to one lateral side of the second inner surface 200a. The horizontal shift of the via pattern of the core/peri pad pattern 232 and the via structure 201 may be caused by a process deviation or the like in the process of forming the core/peri pad pattern 232.

The via pattern of the core/peri pad pattern 232 may be formed to be positioned at a higher level than the bottom surface 200b of the core/peri semiconductor layer 200, or the via pattern of the core/peri pad pattern 232 may be formed to be shifted from the via structure 201. For example, these configurations may represent process variation and/or process non-idealities. Based on the structures and methods described herein, the lower portion of the via structure 201 may be spaced apart from the core/peri semiconductor layer 200 with the recess region RS, e.g., even when process variation and/or non-idealities are present. Thus, the via pattern may not be in contact with the core/peri semiconductor layer 200. Accordingly, semiconductor memory devices with improved electrical properties and structural stability may be provided.

FIG. 9 is an enlarged view of an example of the region A in FIG. 3.

Referring to FIGS. 3 and 9, the via structure 201 may have the through via 202 and the via insulating layer 203. The via insulating layer 203 may include an insulating material. For example, the via insulating layer 203 may include silicon oxide (SiO or SiO₂).

The second passivation layer 241 may cover the bottom surface 200b of the core/peri semiconductor layer 200 and the via structure 201. The second passivation layer 241 may be in contact with the via insulating layer 203 provided on the outer surface of the via structure 201. The second passivation layer 241 may include an oxide of a material constituting the core/peri semiconductor layer 200. For example, the second passivation layer 241 may include silicon oxide (SiO or SiO₂).

The via insulating layer 203 and the second passivation layer 241 may include the same material as each other. For example, the via insulating layer 203 and the second passivation layer 241 may have a continuous configuration, and an interface between the via insulating layer 203 and the second passivation layer 241 may be invisible.

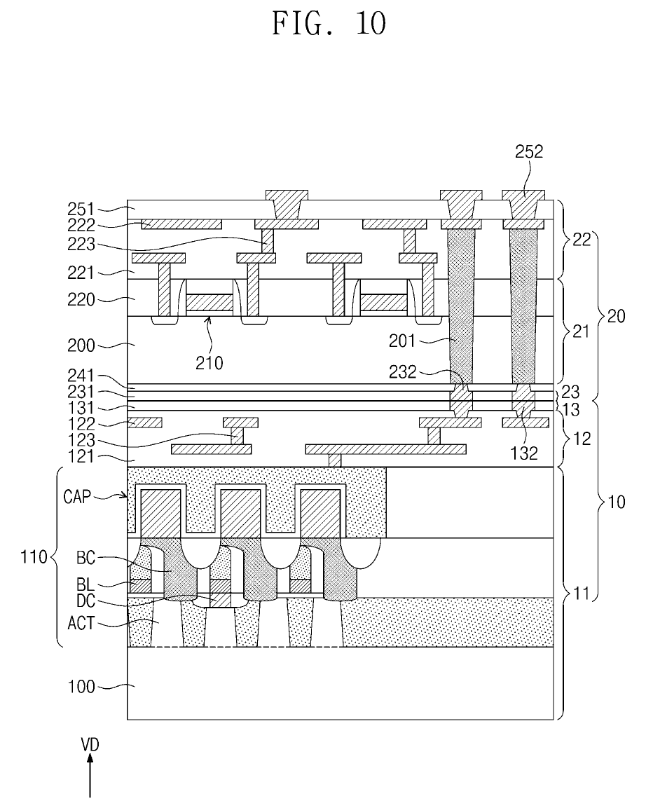

FIG. 10 is a cross-sectional view illustrating an example of a semiconductor memory device.

Referring to FIG. 10, the via structure 201 may be provided in the core/peri chip 20. The via structure 201 may vertically penetrate the third interlayer insulating layer 221, the second interlayer insulating layer 220, and the core/peri semiconductor layer 200 beside of the core/peri transistor 210. One end of the via structure 201 may be connected to the core/peri circuit wirings 222 in the third interlayer insulating layer 221. Otherwise, the descriptions provided with respect to FIGS. 3 to 9 can equally apply to the semiconductor memory device of FIG. 10.

Although FIGS. 3 to 10 show that the cell chip 10 and the core/peri chip 20 are bonded to each other such that the cell wiring layer 12 of the cell chip 10 and the core/peri semiconductor layer 200 of the core/peri chip 20 face each other, the chip configuration is not limited thereto. According to some implementations, the cell chip 10 and the core/peri chip 20 are bonded to each other such that the cell semiconductor layer 100 of the cell chip 10 and the core/peri semiconductor layer 200 of the core/peri chip 20 face each other.

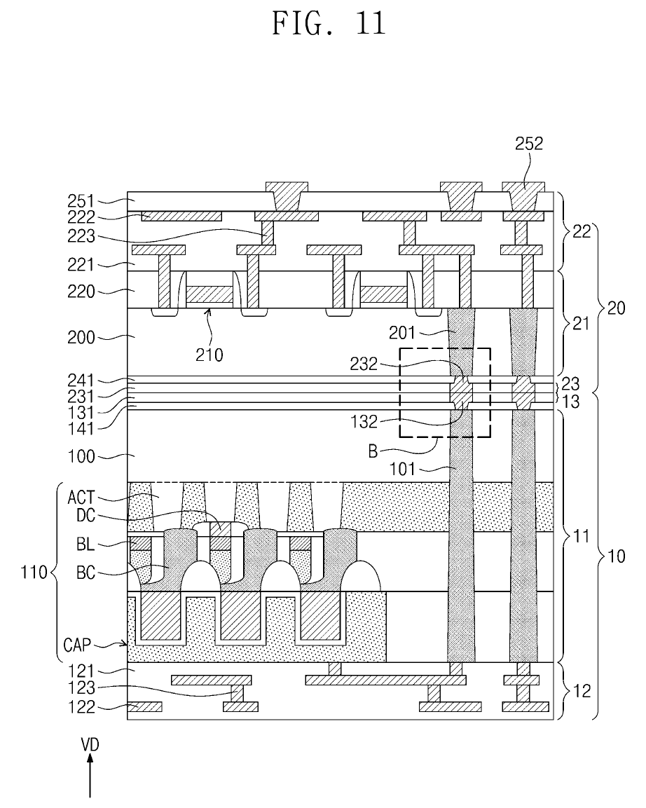

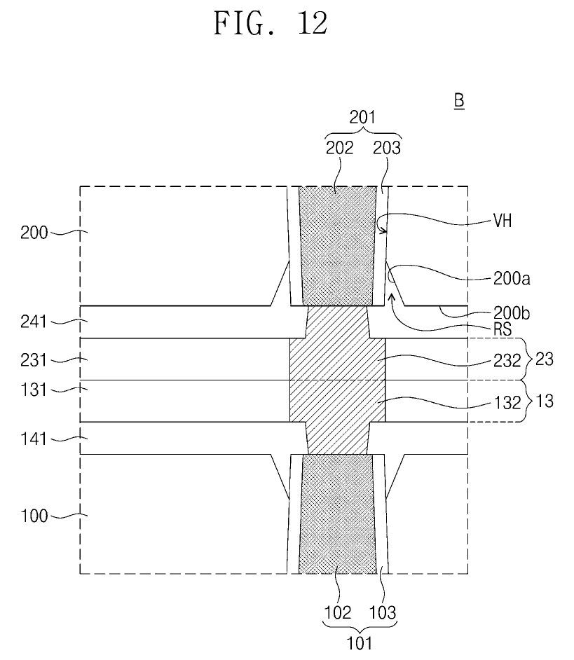

FIG. 11 is a cross-sectional view illustrating an example of a semiconductor memory device. FIG. 12 is an enlarged view of region B of FIG. 11.

With reference to FIGS. 11 and 12, the cell chip 10 may be inverted compared to the cell chip 10 described with reference to FIGS. 3 to 10.

The cell chip 10 may further include a cell via structure 101.

The cell via structure 101 may vertically penetrate the cell semiconductor layer 100 at one side of the semiconductor elements of the memory cell layer 110. For example, the cell semiconductor layer 100 may have a via hole that vertically penetrates the cell semiconductor layer 100. The cell via structure 101 may fill the via hole.

The cell via structure 101 may include a cell via 102 extending in the vertical direction VD and a cell via insulating layer 103 surrounding an outer surface of the cell via 102.

The cell via 102 may have a columnar shape extending in the vertical direction VD. A width of the cell via 102 may be decrease toward the core/peri chip 20. The cell wiring patterns 122, 123 of the cell wiring layer 12 may penetrate the first interlayer insulating layer 121 to be connected to the cell via 102. The cell via 102 may be electrically connected with the memory cell layer 110 through cell wiring patterns 122, 123. The cell via 102 may be exposed on a top surface of the cell semiconductor layer 100. The cell via insulating layer 103 may cover the outer surface of the cell via 102.

The cell via structure 101 may have a columnar shape extending in the vertical direction VD. A width of the cell via structure 101 may be decrease toward the core/peri chip 20. A top surface of the cell via structure 101 may be located at the same vertical level as the top surface of the cell semiconductor layer 100. Alternatively, the top surface of the cell via structure 101 may be located at a higher vertical level than that of cell semiconductor layer 100. A lower portion of an outer surface of the cell via structure 101 may be in contact with the cell semiconductor layer 100. An upper portion of the outer surface of the cell via structure 101 may be spaced apart from the cell semiconductor layer 100.

The cell semiconductor layer 100 may have a recess region provided in the top surface of the cell semiconductor layer 100. The recess region of the cell semiconductor layer 100 may be same as or similar to the recess region RS of the core/peri semiconductor layer 200. For example, the recess region of the cell semiconductor layer 100 may have a shape that is recessed from the top surface of the cell semiconductor layer 100 toward inside of the cell semiconductor layer 100. The recess region may surround the cell via structure 101, in a plan view. The recess region may be in contact with the cell via structure 101. The top surface of the cell semiconductor layer 100 may be horizontally spaced apart from the cell via structure 101 with the recess region. The cell semiconductor layer 100 may have an inclined surface connecting the top surface of the cell semiconductor layer 100 and an inner surface of the via hole.

A third passivation layer 141 may be provided on the top surface of the cell semiconductor layer 100. The third passivation layer 141 may cover the top surface of the cell semiconductor layer 100 and the cell via structure 101. The third passivation layer 141 may fill the recess region of the cell semiconductor layer 100. The third passivation layer 141 may include an insulating material. The third passivation layer 141 may include an oxide of a material of the cell semiconductor layer 100. For example, the third passivation layer 141 may include silicon oxide (SiO or SiO₂). A depth of the recess region of the cell semiconductor layer 100 may range from 40% to 60% of a thickness of the third passivation layer 141. A width of the recess region of the cell semiconductor layer 100 may range from 40% to 60% of the thickness of the third passivation layer 141.

As shown in FIGS. 11 and 12, the cell bonding layer 13 may be provided on the top surface of the third passivation layer 141. The cell bonding layer 13 may include the cell insulating pattern 131 and the cell pad pattern 132.

A cell pad pattern 132 may be provided on the top surface of the third passivation layer 141. The cell pad pattern 132 may vertically penetrate the third passivation layer 141 to be connected to the top surface of the cell via structure 101. For example, the cell pad pattern 132 may include a head pattern disposed on the top surface of the third passivation layer 141, and a via pattern vertically penetrating the third passivation layer 141 to be connected to the cell via structure 101.

The cell insulating pattern 131 may cover the third passivation layer 141. The cell insulating pattern 131 may surround the cell pad pattern 132 on the top surface of the third passivation layer 141.

The top of the cell semiconductor layer 100 may be horizontally spaced apart from the cell via structure 101 with the recess region therebetween. The top surface of the cell semiconductor layer 100 may be horizontally spaced apart from the top surface of the cell via structure 101. Accordingly, the via pattern of the cell pad pattern 132 may not be in contact with the cell semiconductor layer 100. As such, semiconductor memory devices with improved electrical properties and structural stability may be provided.

The core/peri chip 20 may be disposed on the cell chip 10. The core/peri chip 20 may be in direct contact with the cell chip 10.

On an interface between the cell chip 10 and the core/peri chip 20, the cell pad pattern 132 of the cell chip 10 may be bonded to the core/peri pad pattern 232 of the core/peri chip 20. The cell pad pattern 132 and the core/peri pad pattern 232 may be hybrid bonded to each other.

On the interface between the cell chip 10 and the core/peri chip 20, the cell insulating pattern 131 of the cell chip 10 may be in contact with the core/peri insulating pattern 231 of the core/peri chip 20.

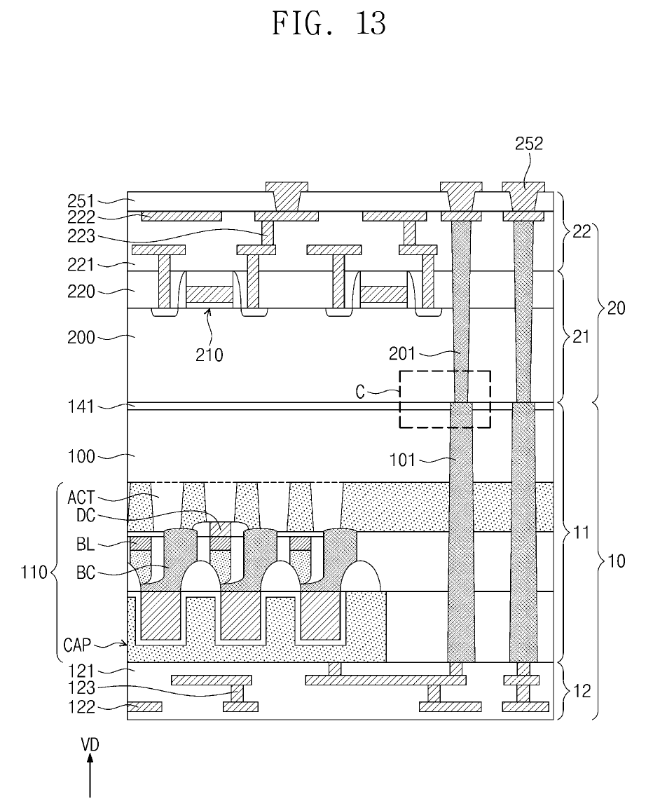

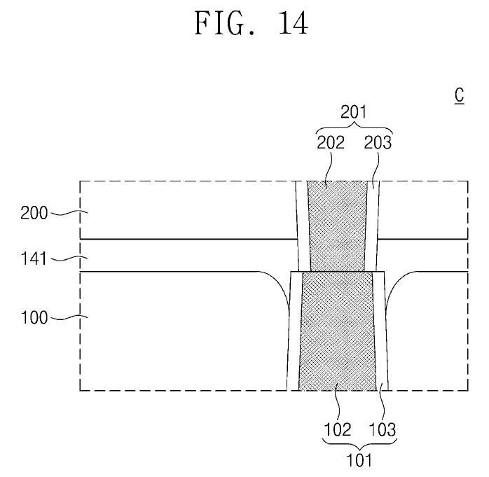

FIG. 13 is a cross-sectional view illustrating an example of a semiconductor memory device. FIG. 14 is an enlarged view of region C of FIG. 13.

In the example of FIGS. 13 and 14, the cell chip 10 and the core/peri chip 20 are bonded to each other such that the cell semiconductor layer 100 of the cell chip 10 and a core/peri semiconductor layer 200 of the core/peri chip 20 face each other.

Referring to FIGS. 13 and 14, as compared with the example of FIGS. 11 and 12, the cell chip 10 may not include the cell bonding layer 13, and the core/peri chip 20 may not include the core/peri bonding layer 23 and the second passivation layer 241.

The core/peri chip 20 may be disposed on the cell chip 10. The core/peri chip 20 may be in direct contact with the cell chip 10.

On the interface between the cell chip 10 and the core/peri chip 20, the third passivation layer 141 of the cell chip 10 may be in contact with the core/peri semiconductor layer 200 of the core/peri chip 20.

On the interface between the cell chip 10 and the core/peri chip 20, the via structure 201 of the core/peri chip 20 and the cell via structure 101 of the cell chip 10 may be in contact with each other. For example, the via structure 201 of the core/peri chip 20 may vertically penetrate the core/peri semiconductor layer 200. The via structure 201 may extend to the third passivation layer 141. The via structure 201 may vertically penetrate the third passivation layer 141 to be connected to the top surface of the cell via structure 101.

The upper portion of the cell semiconductor layer 100 may be horizontally spaced apart from the cell via structure 101 with the recess region. The top surface of the cell semiconductor layer 100 may be horizontally spaced apart from the top surface of the cell via structure 101. An analogous description to that provided for the via structure 201 with respect to FIGS. 3 to 9 can apply to the cell via structure 101. Accordingly, the via structure 201 of the core/peri chip 20 may not be in contact with the cell semiconductor layer 100. A semiconductor memory device with improved electrical properties and structural stability may be provided.

As another example, compared with the example of FIGS. 11 and 12, the cell chip 10 may not include the cell bonding layer 13 and the third passivation layer 141, and the core/peri chip 20 may not include the core/peri bonding layer 23.

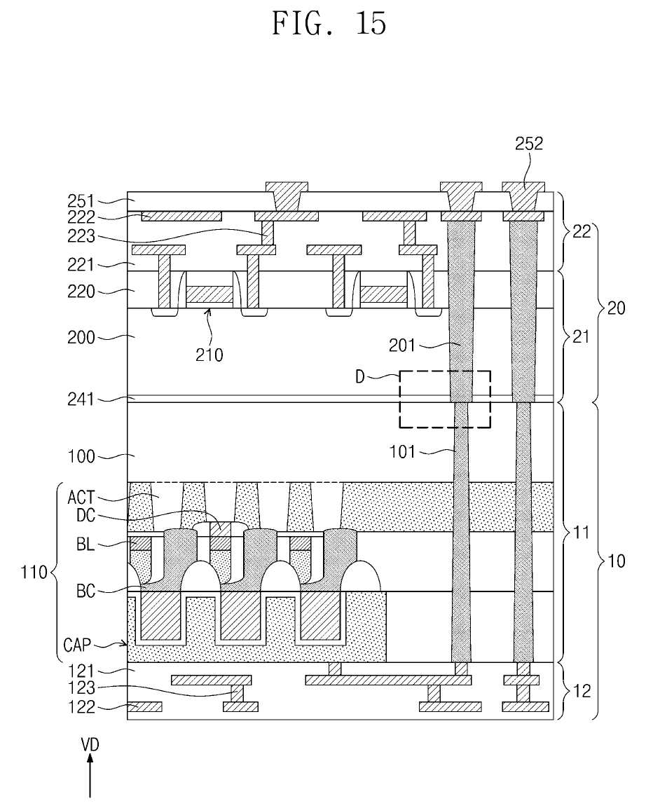

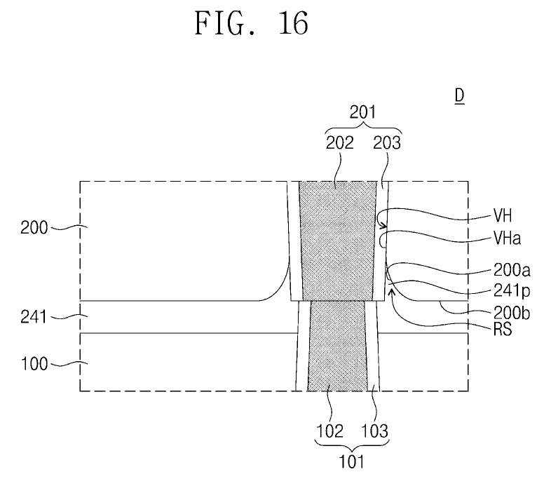

FIG. 15 is a cross-sectional view illustrating an example of a semiconductor memory device. FIG. 16 is an enlarged view of region D of FIG. 15.

Referring to FIGS. 15 and 16, the core/peri chip 20 may be disposed on the cell chip 10. The core/peri chip 20 may be in direct contact with the cell chip 10.

On the interface between the cell chip 10 and the core/peri chip 20, the cell semiconductor layer 100 of the cell chip 10 may be in contact with the second passivation layer 241 of the core/peri chip 20.

On the interface between the cell chip 10 and the core/peri chip 20, the via structure 201 of the core/peri chip 20 and the cell via structure 101 of the cell chip 10 may be in contact with each other. For example, the cell via structure 101 of the cell chip 10 may vertically penetrate the cell semiconductor layer 100. The cell via structure 101 may extend to the second passivation layer 241. The cell via structure 101 may vertically penetrate the second passivation layer 241 to be connected to the bottom surface of the via structure 201.

The lower portion of the core/peri semiconductor layer 200 may be horizontally spaced apart from the via structure 201 with the recess region RS therebetween. The bottom surface of the core/peri semiconductor layer 200 may be horizontally spaced apart from the bottom surface of the via structure 201. Accordingly, the cell via structure 101 of the cell chip 10 may not be in contact with the core/peri semiconductor layer 200. A semiconductor memory device with improved electrical characteristics and structural stability may be provided.

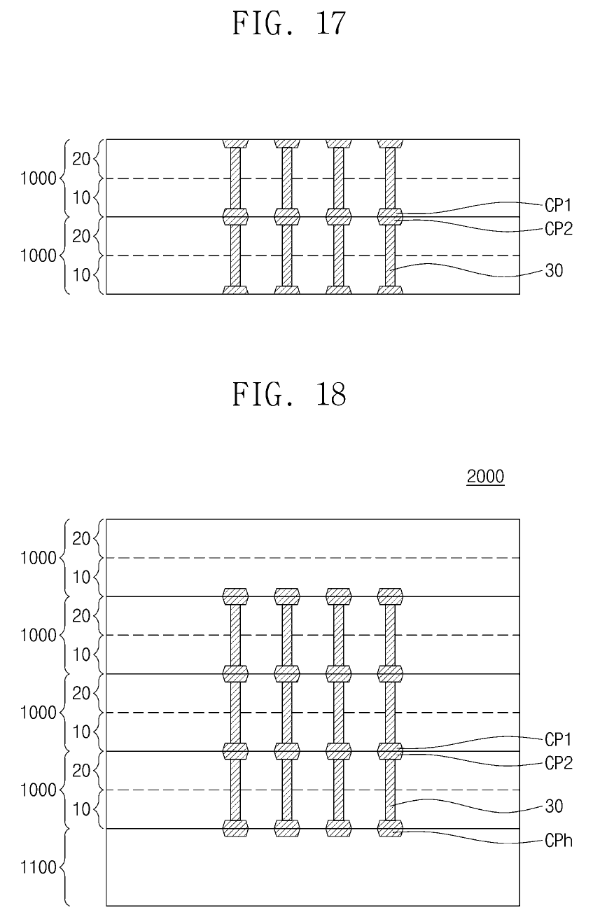

FIG. 17 is a cross-sectional view illustrating an example of a configuration of a plurality of semiconductor memory devices.

Referring to FIG. 17, a plurality of memory chips 1000 may be provided. The memory chips 1000 may be the same as or similar to the memory chips described with reference to FIGS. 3 to 16. For example, each of the memory chips 1000 may include the cell chip 10 and the core/peri chip 20. The cell chip 10 and the core/peri chip 20 may be substantially the same as or similar to the cell chips 10 and core/peri chips 20 described with reference to FIGS. 3 to 16. Each of the cell chip 10 and the core/peri chip 20 may include through vias 30. The through vias 30 may correspond to the via structure 201 or the cell via structure 101 described with reference to FIGS. 3 to 16. The plurality of cell chips 10 and a plurality of core/peri chips 20 may be alternately stacked. In FIG. 17, two memory chips 1000 are shown, but the number is not limited thereto, and three or more memory chips 1000 may be stacked.

The memory chips 1000 may be electrically connected to each other via through vias 30. The through vias 30 of the memory chips 1000 may include through vias 30 in the cell chip 10 and through vias 30 on the core/peri chip 20. Although FIG. 17 shows the through vias 30 of the cell chip 10 and the through vias of the core/peri chip 20 as physically connected, the connction is not limited thereto, and may be connected to each other through separate contacts provided therebetween (for example, a cell bonding layer and a core/peri bonding layer described with reference to FIGS. 3 to 16, and the like).

The through vias 30 of a pair of memory chips 1000 disposed perpendicular to each other may be electrically connected through a first contact pad CP1 and a second contact pad CP2. The first contact pad CP1 and the second contact pad CP2 may be in contact with each other. Each of the first and second contact pads CP1 and CP2 may be a conductive pad or a conductive bump.

FIG. 18 is a cross-sectional view illustrating an example of a semiconductor package including a semiconductor memory device.

Referring to FIG. 18, a semiconductor package 2000 may include a base chip 1100 and the plurality of memory chips 1000 on the base chip 1100. The base chip 1100 may be electrically coupled with a plurality of memory chips 1000. The base chip 1100 may include a host core or a buffer die. The host core may include a processor that performs various computational tasks. The buffer die may receive externally transmitted instructions, data, signals, etc., and transmit them to the plurality of memory chips 1000. In other words, the plurality of memory chips 1000 may be connected to the base chip 1100 and used to perform various operations according to signals received therefrom.

The plurality of memory chips 1000 may be electrically connected to the base chip 1100 through the through vias 30. For example, the base chip 1100 may include a base contact pad CPh disposed on a top surface of the base chip 1100, and the through vias 30 may be connected to the base chip 1100 through the base contact pad CPh. For example, the through vias 30 may not be provided in an uppermost memory chip 1000, but the through via configuration is not limited thereto.

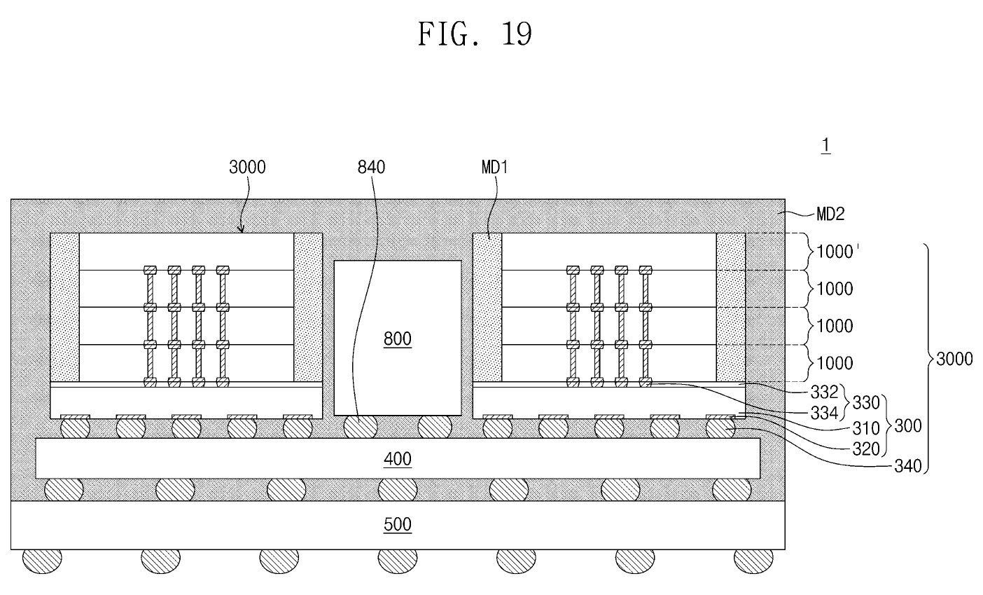

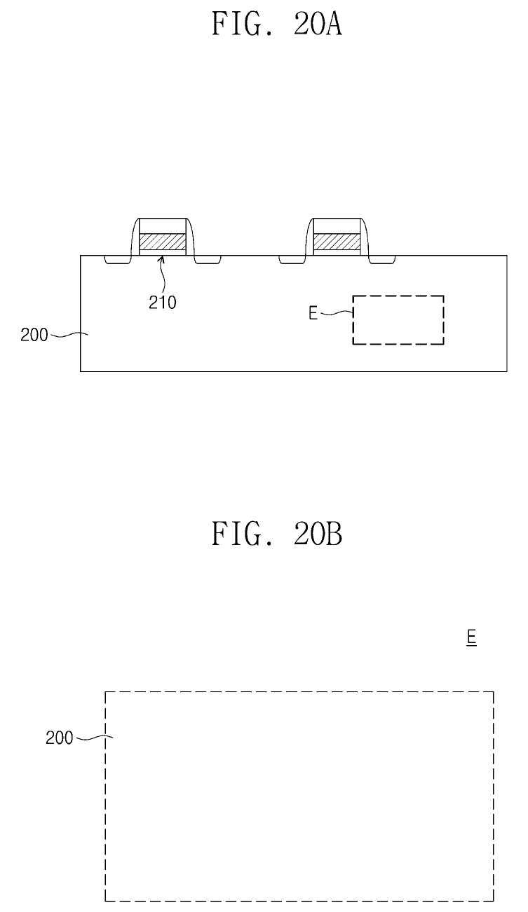

FIG. 19 is a cross-sectional view illustrating an example of a semiconductor package including a semiconductor memory device.

Referring to FIG. 19, a semiconductor package 1 may include package substrates 400 and 500, a memory structure 3000, and a host structure 800. The memory structure 3000 and the host structure 800 may be provided on the package substrates 400, 500 and may be horizontally spaced apart from each other. The memory structure 3000 and the host structure 800 may be electrically connected to each other through the package substrates 400, 500.

For example, the package substrates 400, 500 may include a first package substrate 400 and a second package substrate 500. The first package substrate 400 may be disposed on a second package substrate 500, and the memory structure 3000 and the host structure 800 may be disposed on the first package substrate 400. The first package substrate 400 may be an interposer, and the second package substrate 500 may be a printed circuit board (PCB). A first connection terminal may electrically connect the first package substrate 400 and the second package substrate 500. A second connection terminal may electrically connect the semiconductor package 1 to an external device (for example, a main board).

The memory structure 3000 may include a base chip 300, a plurality of memory chips 1000 and 1000′ on the base chip 300, the first molding layer MD1 surrounding the plurality of memory chips 1000 and 1000′, and a memory connection terminal 340 between the base chip 300 and the first package substrate 400. The base chip 300 may correspond to the base chip 1100 of FIG. 18.

The base chip 300 may include a base layer 310, an upper wiring layer 330 formed on one surface (e.g., a top surface) of the base layer 310, and a lower base pad 320 exposed by the other surface (e. g., a bottom surface) of the based layer 310. The upper wiring layer 330 may include an upper base pad 332 and a base protective layer 334 surrounding the upper base pad 332.

The base chip 300 may redistribute the plurality of memory chips 1000, 1000′. The upper base pad 332 and the lower base pad 320 may be electrically connected by circuit wiring in the base layer 310, and may constitute a redistribution circuit together with the circuit wiring. The memory connection terminal 340 may be disposed between the lower base pad 320 and the first package substrate 400. The memory connection terminal 340 may include a solder ball, a solder bump, or the like. The first molding layer MD1 may include an insulating material. For example, the first molding layer MD1 may include an epoxy molding compound EMC.

The host structure 800 may be a data processing device. A host connection terminal 840 may be interposed between the host structure 800 and the first package substrate 400. The host connection terminal 840 may electrically connect the host structure 800 and the first package substrate 400.

A second molding layer MD2 may be disposed on the first package substrate 400 and surround the memory structure 3000 and the host structure 800. The second molding layer MD2 may include an insulating material. For example, the second molding layer MD2 may include an epoxy molding compound (EMC).

FIGS. 20A to 26A are cross-sectional views illustrating an example of a method of manufacturing a semiconductor memory device. FIGS. 20B to 26B are enlarged views illustrating the method, and correspond to an E region of FIGS. 20A to 26A.

Referring to FIGS. 20A and 20B, a core/peri semiconductor layer 200 may be provided. The core/peri semiconductor layer 200 may be a semiconductor substrate including a semiconductor material, such as a single crystal silicon substrate.

A core/peri transistor 210 may be formed on the core/peri semiconductor layer 200. For example, a dielectric layer and a conductive layer may be formed on the core/peri semiconductor layer 200, the dielectric layer and the conductive layer may be patterned to form a gate insulating layer and a gate electrode, a gate spacer may be formed on a side surface of the gate electrode, and impurities may be injected to an upper portion of the core/peri semiconductor layer 200 on one side of the gate spacer to form a source and a drain. However, the transistor fabrication and configuration is not limited thereto, and the core/peri transistor 210 may be formed in various ways, and the form of the core/peri transistor 210 is also not limited to a planar transistor.

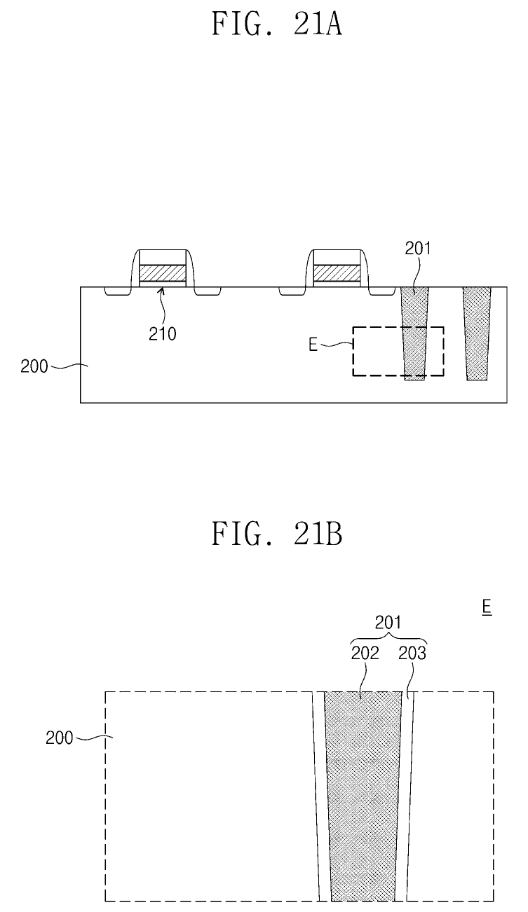

Referring to FIGS. 21A and 21B, a via structure 201 may be formed in the core/peri semiconductor layer 200. For example, a via hole may be formed in the core/peri semiconductor layer 200. The via hole may extend from a top surface of the core/peri semiconductor layer 200 toward an inside of the core/peri semiconductor layer 200. A width of the via hole may decrease toward a bottom surface of the core/peri semiconductor layer 200. The via hole may be spaced apart from the bottom surface of the core/peri semiconductor layer 200. The via hole may not completely penetrate the core/peri semiconductor layer 200. A via insulating layer 203 that covers an inner surface and a bottom surface of the via hole is formed, and a conductive material may be filled in the remainder of the via hole to form a through via 202. The through via 202 and the via insulating layer 203 may constitute the via structure 201.

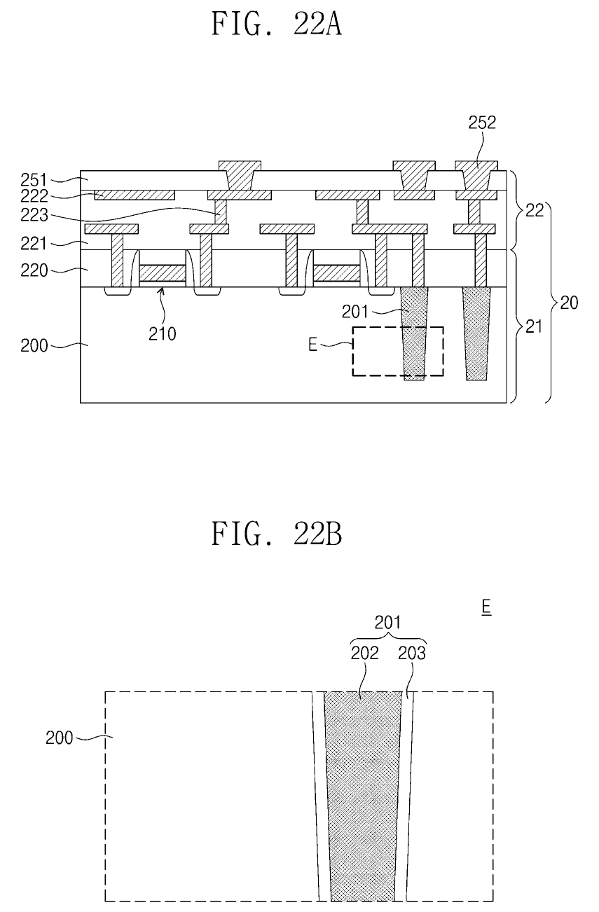

Referring to FIGS. 22A and 22B, an insulating material may be applied or deposited on the top surface of the core/peri semiconductor layer 200 to form a second interlayer insulating layer 220. The second interlayer insulating layer 220 may cover the core/peri transistor 210. The core/peri semiconductor layer 200, the core/peri transistor 210, and the second interlayer insulating layer 220 may constitute a driving layer 21. A thinning process may be performed on a top surface of the driving layer 21. The top surface of the driving layer 21 may be polished by the thinning process. For example, a planarization process such as chemical mechanical polishing (CMP) may be performed on the top surface of the driving layer 21. A thickness of the second interlayer insulating layer 220 may be reduced by the thinning process. The thinning process may be performed until a top surface of the core/peri transistor 210 is exposed. However, the thinning process is not limited thereto.

A core/peri wiring layer 22 may be formed on the driving layer 21. For example, on the top surface of the driving layer 21, deposition of an insulating layer, patterning of the insulating layer, deposition of a conductive layer, and patterning of the conductive layer may be repeatedly performed to form core/peri circuit wirings 222, core/peri contact plugs 223 and a third interlayer insulating layer 221. The core/peri contact plugs 223 may electrically connect the core/peri transistor 210 and the via structure 201 to the core/peri circuit wirings 222. However, the method for forming the core/peri wiring layer 22 is not limited thereto.

According to some implementations, the via structure 201 may be formed together during the process of forming the core/peri wiring layer 22, or may be formed after the core/peri wiring layer 22 is formed. That is, a variety of process orders are within the scope of this disclosure.

An insulating material may be deposited on the core/peri wiring layer 22 to form a first passivation layer 251. After patterning the first passivation layer 251 to form patterns exposing the core/peri circuit wirings 222, a conductive layer may be deposited and patterned on the first passivation layer 251 to form a chip pads 252. As another example, the first passivation layer 251 and the chip pads 252 may be formed after a subsequent process is performed.

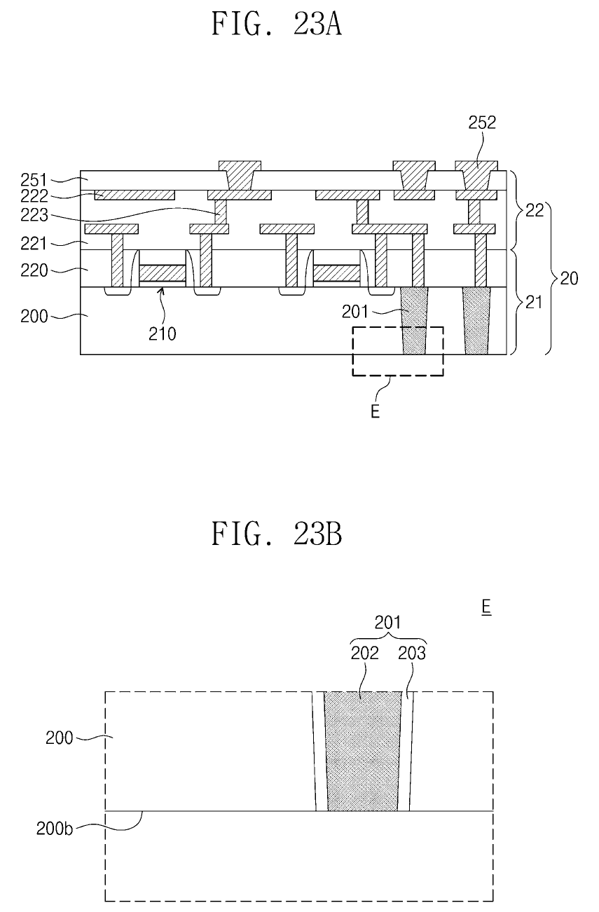

Referring to FIGS. 23A and 23B, a thinning process may be performed on a rear surface (e.g., a bottom surface) of the core/peri semiconductor layer 200. The rear surface of the core/peri semiconductor layer 200 may be polished by the thinning process. For example, a planarization process such as chemical mechanical polishing (CMP) may be performed on the rear surface of the core/peri semiconductor layer 200. A thickness of the core/peri semiconductor layer 200 may be reduced by the thinning process. The rear surface of the core/peri semiconductor layer 200 may be planarized. The thinning process may be performed until the bottom surface of the via structure 201 is exposed. During the thinning process, a portion of the via insulating layer 203 provided on the bottom surface of the through via 202 may be removed together. After the thinning process, a first bottom surface of the core/peri semiconductor layer 200 may be removed and a bottom surface 200b of the core/peri semiconductor layer 200 (second bottom surface 200b) located at a higher level than the first bottom surface may be formed. The first bottom surface of the core/peri semiconductor layer 200 refers to the bottom surface of the core/peri semiconductor layer 200 before the thinning process, and the second bottom surface 200b refers to the bottom surfaces of the core/peri semiconductor layer 200 after the thinning process. The second bottom surface 200b, the bottom surface of the through via 202 and a bottom surface of the via insulating layer 203 may be substantially in the same level. On the second bottom surface 200b, a width of the via structure 201 may be less than a width of the top surface of the via structure 201.

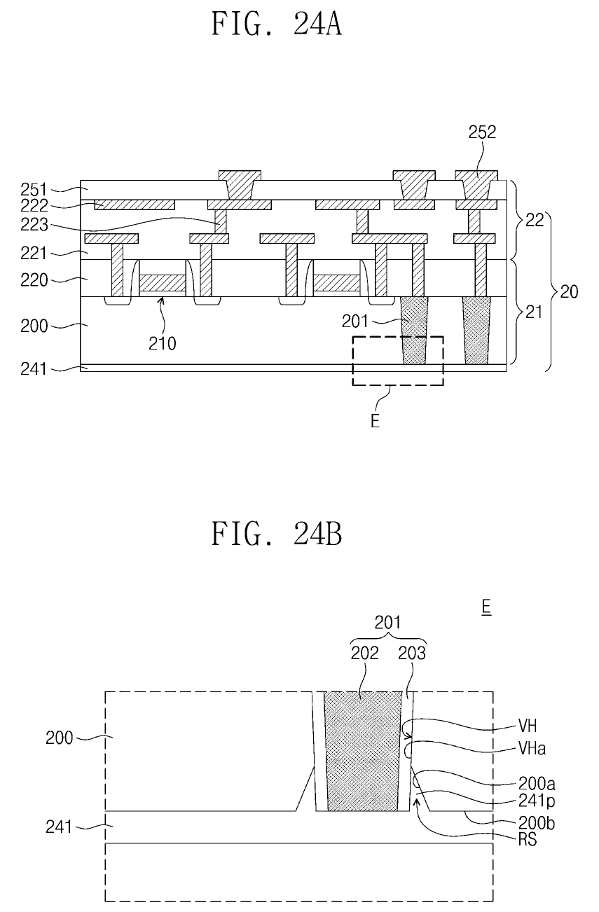

Referring to FIGS. 24A and 24B, an oxidation process may be performed on the second bottom surface 200b of the core/peri semiconductor layer 200. For example, a portion of the core/peri semiconductor layer 200 exposed to the second bottom surface 200b of the core/peri semiconductor layer 200 may be oxidized to form the second passivation layer 241. A portion of the core/peri semiconductor layer 200 adjacent to the via structure 201 may be oxidized at a higher rate during the oxidation process. A recess region RS may be formed at the second bottom surface 200b of the core/peri semiconductor layer 200. The recess region RS may have a shape recessed from the second bottom surface 200b of the core/peri semiconductor layer 200 toward an inside of the core/peri semiconductor layer 200. The recess region RS may surround the via structure 201 in a plan view. The second passivation layer 241 may fill the recess region RS. The second bottom surface 200b of the core/peri semiconductor layer 200 may be horizontally spaced apart from the via structure 201 with the recess region RS. A lower portion of the via structure 201 may be spaced apart from a lower portion of the core/peri semiconductor layer 200 with the second passivation layer 241 filling the recess region RS. After the oxidation process, the second bottom surface 200b of the core/peri semiconductor layer 200 and the bottom surface of the via structure 201 may be located at the same vertical level. As another example, after the oxidation process, the bottom surface of the via structure 201 may be located at a lower vertical level than the bottom surface of the second bottom surface 200b of the core/peri semiconductor layer 200. That is, the via structure 201 may protrude from the second bottom surface 200b of the core/peri semiconductor layer 200.

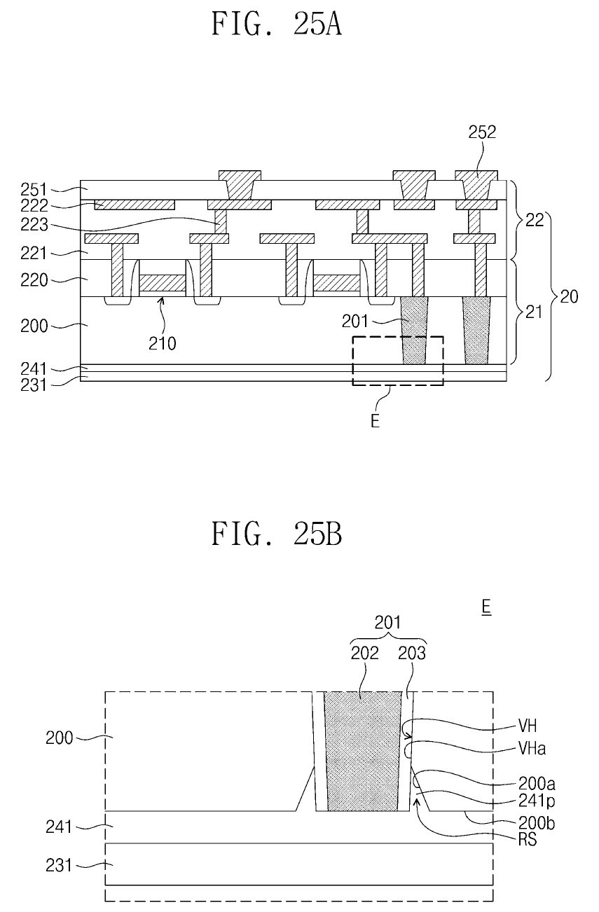

Referring to FIGS. 25A and 25B, a core/peri insulating pattern 231 may be formed on a bottom surface of the second passivation layer 241. For example, a deposition process of an insulating layer may be performed on the bottom surface of the second passivation layer 241 to form the core/peri insulating pattern 231. If necessary, the deposition process of the insulating layer may be repeatedly performed.

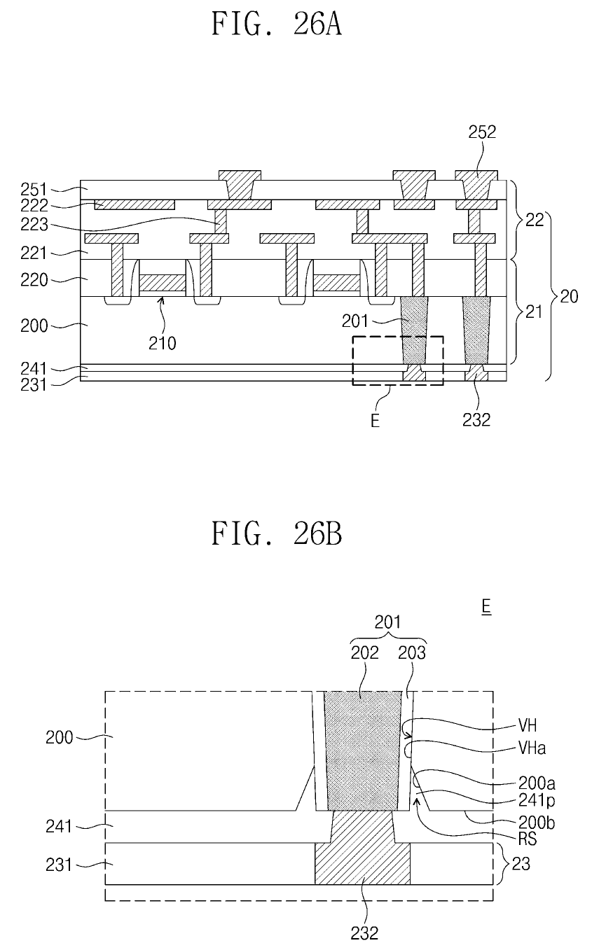

Referring to FIGS. 26A and 26B, a core/peri pad pattern 232 may be formed. For example, the core/peri insulating pattern 231 and the second passivation layer 241 may be patterned to form a hole exposing the bottom surface of the via structure 201, and the hole may be filled with a conductive material to form the core/peri pad pattern 232.

The core/peri insulating pattern 231 and the core/peri pad pattern 232 may constitute a core/peri bonding layer 23. However, the method for forming the core/peri bonding layer 23 is not limited thereto.

In the process of forming the via hole VH, an etching direction of the core/peri semiconductor layer 200 may be from the top surface of the core/peri semiconductor layer 200 toward the second bottom surface 200b. Thus, the width of the bottom surface of the via structure 201 may be less than a width of the top surface of the via structure 201. When the core/peri pad pattern 232 and the via structure 201 are misaligned during the formation of the core/peri bonding layer 23, the core/peri pad pattern 232 may be in contact with the core/peri semiconductor layer 200, absent configurations to prevent the contact.

According to some implementations of the present disclosure, in the process of forming the second passivation layer 241, a portion of the core/peri semiconductor layer 200 adjacent to the via structure 201 may be removed. The core/peri semiconductor layer 200 may be spaced apart from the via structure 201 on a plane in which the second bottom surface 200b of the core/peri semiconductor layer 200 is located. Thus, even if the via pattern of the core/peri pad pattern 232 is shifted horizontally from the via structure 201, the via pattern of core/peri pad pattern 232 may be spaced apart from the core/peri semiconductor layer 200. That is, the core/peri semiconductor layer 200 may not be damaged due to the via pattern of the core/peri pad pattern 232 is in contact with the core/peri semiconductor layer 200. In addition, defects such as contamination by metal materials may not occur. Accordingly, a method of manufacturing a semiconductor memory device in which the occurrence of process defects is small may be provided.

Referring again to FIG. 3, a cell chip 10 may be formed. The cell chip 10 may include a data storage layer 11 and a cell wiring layer 12.

The data storage layer 11 may include a cell semiconductor layer 100 and a memory cell layer 110. The memory cell layer 110 may include a DRAM cell structure including an active region ACT, a bit line node contact DC, a bit line BL, a storage node contact BC, a capacitor CAP, and the like.

The cell wiring layer 12 may be formed on the data storage layer 11. For example, deposition of an insulating layer, patterning of the insulating layer, deposition of a conductive layer, and patterning of the conductive layer may be repeatedly performed on a top surface of the data storage layer 11 to form a cell circuit wiring 122, a cell contact plug 123, and a first interlayer insulating layer 121. The cell contact plugs 123 may electrically connect the memory cell layer 110 and the cell circuit wiring 122. However, the method for forming the cell wiring layer 12 is not limited thereto.

A cell insulating pattern 131 may be formed on the cell wiring layer 12. For example, a cell insulating pattern 131 may be formed on a top surface of the cell wiring layer 12 by performing a deposition process of an insulating layer. If necessary, the deposition process of the insulating layer may be repeatedly performed. A cell pad pattern 132 may be formed. For example, the cell insulating pattern 131 and the first interlayer insulating layer 121 may be patterned to form a hole exposing the cell circuit wirings 122, and a conductive material may be filled in the hole to form the cell pad pattern 132.

The cell insulating pattern 131 and the cell pad pattern 132 may constitute a cell bonding layer 13. However, the method for forming the cell bonding layer 13 is not limited thereto.

A core/peri chip 20 may be bonded to the cell chip 10. The core/peri chip 20 may be aligned on the cell chip 10 such that the cell pad pattern 132 and the core/peri pad pattern 232 face each other. The core/peri chip 20 may be disposed on the cell chip 10 such that the cell insulating pattern 131 and the core/peri insulating pattern 231 are in contact with each other. A heat treatment process may be performed on the cell pad pattern 132 and the core/peri pad pattern 232. The cell pad pattern 132 and the core/peri pad pattern 232 may be bonded by the heat treatment process. For example, the cell pad pattern 132 and the core/peri pad pattern 232 may be combined to form an integral body. Specifically, the cell pad pattern 132 and the core/peri pad pattern 232 may be made of the same material (e.g., a metal such as copper (Cu)), and the cell pad pattern 132 and the core/peri pad pattern 232 may be bonded to each other by an intermetallic hybrid bonding process by surface activation at an interface between the cell pad patterns 132 and core/peri pad pattern 232 that are in contact with each other.

In some implementations of the semiconductor memory devices described herein, even if the width of the via pattern connected to the bottom surface of the via structure is large or the via structure and the via pattern are misaligned, the via pattern may not be in contact with the semiconductor layer. Accordingly, leakage current due to contact between the via pattern and the semiconductor layer may not occur, and a semiconductor memory device with improved electrical characteristics may be provided. Further, the semiconductor layer may not be damaged by the via pattern or contaminated by the via pattern made of metal. That is, a semiconductor memory device with improved structural stability and a method for manufacturing a semiconductor memory device in which defects are less likely to occur may be provided.

According to some implementations of the present disclosure, a method for manufacturing a semiconductor memory device may include: forming a semiconductor element on a first surface of a first semiconductor substrate; forming a via hole in the first semiconductor substrate; forming a via structure filling the via hole; performing a thinning process on a second surface of the first semiconductor substrate that opposites to the first surface to form a third surface that opposites to the first surface, the third surface exposing the via structure; and performing an oxidation process on the third surface of the first semiconductor substrate to form a passivation layer. During the oxidation step, a portion of the first semiconductor substrate adjacent to the third surface may be oxidized to form the passivation layer. During the oxidation process, a recess region provided on the third surface of the first semiconductor substrate and surrounding the via structure may be formed. The passivation layer may fill inside of the recess region.

In some implementations, the method may further include: forming an insulating pattern on the passivation layer; and forming a via pattern that penetrates the insulating pattern and the passivation layer to be connected to the via structure. The via pattern may be horizontally spaced apart from the third surface of the first semiconductor substrate.

In some implementations, the method may further include: forming a first pad pattern provided within the insulating pattern; forming a second pad pattern on the second semiconductor substrate; and bonding the second semiconductor substrate on the first semiconductor substrate such that the first pad pattern and the second pad pattern are in contact with each other.

In some implementations, forming the via structure may include: forming a via insulating layer covering an inner surface and a bottom surface of the via hole; and filling remainder of the via hole with a conductive material to form a through via. During the thinning process, a portion of the via insulating layer covering a bottom surface of the through via may be removed to expose the bottom surface of the though via.

In some implementations, a depth and a width of the recess region may range from 40% to 60% of a thickness of the passivation layer.

In some implementations, the depth and the width of the recess region may range from 400 Angstrom to 600 Angstrom.

In some implementations, the first semiconductor substrate may include a fourth surface connecting the via hole and the third surface. The recess region may be defined by at least a portion of an outer surface of the via structure and the fourth surface of the first semiconductor substrate. The fourth surface of the first semiconductor substrate may be a convex surface.

In some implementations, the third surface of the first semiconductor substrate may be horizontally spaced apart from the via structure with the recess region therebetween.

In some implementations, a width of the via hole may decrease as from the first surface toward the third surface.

In some implementations, after the oxidation process, the via structure may protrude from the third surface of the first semiconductor substrate.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A semiconductor memory device comprising:
a first semiconductor structure including a first semiconductor substrate and a first semiconductor element layer on a first surface of the first semiconductor substrate; and
a second semiconductor structure on the first semiconductor structure, the second semiconductor structure including a second semiconductor substrate and a second semiconductor element layer on a second surface of the second semiconductor substrate,
wherein the second semiconductor structure comprises:
a first via structure extending vertically in the second semiconductor substrate and connected to the second semiconductor element layer; and
a passivation layer covering a third surface of the second semiconductor substrate, wherein the third surface is opposite the second surface,
wherein the second semiconductor substrate defines a recess region on the third surface, wherein the recess region surrounds the first via structure, and
wherein the passivation layer includes a protrusion that fills the recess region, the passivation layer being in contact with the first via structure.

2. The semiconductor memory device of claim 1, wherein the third surface of the second semiconductor substrate is horizontally spaced apart from the first via structure with the recess region therebetween.

3. The semiconductor memory device of claim 1, wherein the first via structure comprises:
a through via extending vertically in the second semiconductor substrate; and
a via insulating layer surrounding an outer surface of the through via.

4. The semiconductor memory device of claim 3, wherein:
the via insulating layer includes silicon oxide,
the passivation layer includes silicon oxide, and
the via insulating layer and the passivation layer include a same material.

5. The semiconductor memory device of claim 1, wherein the second semiconductor substrate:
defines a via hole extending vertically in the second semiconductor substrate, wherein the first via structure is in the via hole; and
comprises a fourth surface connecting an inner surface of the via hole with the third surface,
wherein the recess region is defined by at least a portion of an outer surface of the first via structure and the fourth surface of the second semiconductor substrate, and
wherein the fourth surface of the second semiconductor substrate comprises a convex surface.

6. The semiconductor memory device of claim 1, wherein a width of the first via structure decreases in a direction from the second surface of the second semiconductor substrate to the third surface of the second semiconductor substrate.

7. The semiconductor memory device of claim 1, wherein the first via structure protrudes below the third surface of the second semiconductor substrate.

8. The semiconductor memory device of claim 1, wherein each of a vertical depth of the recess region and a horizontal width of the recess region is in a range from 40% to 60% of a thickness of the passivation layer.

9. The semiconductor memory device of claim 8, wherein each of the vertical depth and the horizontal width of the recess region is in a range from 400 Angstrom to 600 Angstrom.

10. The semiconductor memory device of claim 1, wherein:
the second semiconductor structure includes a first bonding layer on the passivation layer,
the first bonding layer comprises:
a first insulating pattern covering the passivation layer;
a first pad pattern in the first insulating pattern; and
a via pattern extending from a surface of the first pad pattern and extending through the passivation layer to connect to the first via structure, and
the via pattern is horizontally spaced apart from the third surface of the second semiconductor substrate.

11. The semiconductor memory device of claim 10, wherein:
the first semiconductor structure comprises a second bonding layer,
the second bonding layer comprises:
a second insulating pattern; and
a second pad pattern in the second insulating pattern and electrically connected to the first semiconductor element layer,
the first insulating pattern and the second insulating pattern are in contact with each other, and
the first pad pattern and the second pad pattern are in contact with each other.

12. The semiconductor memory device of claim 1, wherein the first semiconductor structure includes a second via structure connected to the first semiconductor element layer, wherein the second via structure extends in the first semiconductor substrate and the passivation layer to connect to the first via structure, and
wherein the second via structure is horizontally spaced apart from the third surface of the second semiconductor substrate.

13. The semiconductor memory device of claim 1, wherein:
the first semiconductor element layer includes:
word lines disposed on a cell array region of the first semiconductor substrate;
bit lines disposed on the cell array region and intersecting the word lines; and
an interlayer insulating layer on the first semiconductor substrate,
the word lines are embedded in the first semiconductor substrate, and
the bit lines are on the first semiconductor substrate.

14. The semiconductor memory device of claim 1, wherein the second semiconductor substrate comprises a core region and a peripheral circuit region electrically connected to the core region.

15. A semiconductor memory device comprising:
a first semiconductor substrate comprising a cell array region;
a first interlayer insulating layer covering the first semiconductor substrate;
first wirings in the first interlayer insulating layer and electrically connected to the cell array region;
a first bonding layer on the first interlayer insulating layer;
a second semiconductor substrate on the first bonding layer, the second semiconductor substrate comprising a logic region electrically connected to the cell array region;
a transistor on a top surface of the second semiconductor substrate on the logic region;
a second interlayer insulating layer covering the top surface of the second semiconductor substrate;
second wirings in the second interlayer insulating layer and electrically connected to the transistor;
a passivation layer covering a bottom surface of the second semiconductor substrate;
a second bonding layer covering a bottom surface of the passivation layer and in contact with the first bonding layer; and
a via structure in a via hole that extends vertically in the second semiconductor substrate,
wherein the second semiconductor substrate comprises an inclined surface connecting an inner surface of the via hole with the bottom surface of the second semiconductor substrate,
wherein the via structure is horizontally spaced apart from the bottom surface of the second semiconductor substrate,
wherein the second bonding layer includes a via pattern, and
wherein the via pattern extends in the passivation layer to connect to a bottom surface of the via structure, and is horizontally spaced apart from the bottom surface of the second semiconductor substrate.

16. The semiconductor memory device of claim 15, wherein the passivation layer is in contact with a lower portion of an outer surface of the via structure, the inclined surface of the second semiconductor substrate, and the bottom surface of the second semiconductor substrate.

17. The semiconductor memory device of claim 15, wherein:
a distance from the bottom surface of the second semiconductor substrate to an uppermost end of the inclined surface is in a range from 40% to 60% of a thickness of the passivation layer, and
a distance from a bottom surface of the via structure to the bottom surface of the second semiconductor substrate in in a range from 40% to 60% of the thickness of the passivation layer.

18. The semiconductor memory device of claim 15, wherein an uppermost end of the via pattern is located at a higher level than the bottom surface of the second semiconductor substrate.

19. The semiconductor memory device of claim 15, wherein the passivation layer includes an oxide of a semiconductor material constituting the second semiconductor substrate.

20. A semiconductor memory device comprising:
a first semiconductor substrate;
a first semiconductor structure including a first semiconductor element layer on the first semiconductor substrate;
a first bonding layer on the first semiconductor structure;
a second semiconductor substrate on the first bonding layer;
a second semiconductor structure including a second semiconductor element layer on the second semiconductor substrate;
a via structure extending vertically in the second semiconductor substrate;
a passivation layer covering a bottom surface of the second semiconductor substrate; and
a second bonding layer covering the passivation layer and in contact with the first bonding layer,
wherein an upper portion of the via structure is in contact with the second semiconductor substrate,
wherein a lower portion of the via structure is horizontally spaced apart from the second semiconductor substrate,
wherein a portion of the passivation layer is between the lower portion of the via structure and the second semiconductor substrate,
wherein the first bonding layer includes a first insulating pattern and a first pad pattern in the first insulating pattern,
wherein the second bonding layer includes a second insulating pattern, a second pad pattern in the second insulating pattern, and a via pattern that extends in the second insulating pattern and the passivation layer to connect to a bottom surface of the via structure, and
wherein the first pad pattern and the second pad pattern are in contact with each other.
